(19) United States
(12) Patent Application Publication
(10) Pub. No.: US 2026/0282921 A1
(43) Pub. Date: Sep. 17, 2026

(54) SEMICONDUCTOR DEVICE AND METHOD OF MANUFACTURING SEMICONDUCTOR DEVICE

(71) Applicants: KABUSHIKI KAISHA TOSHIBA, Kawasaki-shi (JP); Toshiba Electronic Devices & Storage Corporation, Kawasaki-shi (JP)

(72) Inventors: Fumiyoshi KAWASHIRO, Tokyo (JP); Eitaro MIYAKE, Tokyo (JP); Yutaro HAYASHI, Kanagawa (JP); Kazuya MARUYAMA, Tokyo (JP); Kazushiro NOMURA, Kawasaki (JP); Nozomu KOIDE, Yokohama (JP)

(73) Assignees: KABUSHIKI KAISHA TOSHIBA, Kawasaki-shi (JP); Toshiba Electronic Devices & Storage Corporation, Kawasaki-shi (JP)

(21) Appl. No.: 19/312,355

(22) Filed: Aug. 28, 2025

(30) Foreign Application Priority Data
Mar. 11, 2025 (JP) 2025-038175

(51) Int. Cl. H01L 23/00; H01L 21/48; H01L 21/56; H01L 23/31; H01L 23/495

(52) U.S. Cl. CPC H10W 42/121; H10W 70/041; H10W 70/417; H10W 70/481; H10W 74/016; H10W 74/111; H10W 72/07336; H10W 72/322; H10W 72/352; H10W 72/623

(57) ABSTRACT

A semiconductor device includes a semiconductor chip having a first chip surface facing a first side of a first direction and having a second chip surface facing a second side of the first direction. A first electrode terminal faces the first chip surface in the first direction, and a second electrode terminal faces the second chip surface in the first direction. A bonding material of solder bonds the semiconductor chip and each of the first electrode terminal and the second electrode terminal. The bonding material includes first and second bonding materials. The first includes a first bonding layer bonded to the first chip surface. The second includes a second bonding layer that bonds the first bonding layer and the first electrode terminal. A weight proportion of lead in the second bonding material is less than a weight proportion of lead in the first bonding material.

### CROSS-REFERENCE TO RELATED APPLICATION

This application is based upon and claims the benefit of priority from Japanese Patent Application No. 2025-038175, filed Mar. 11, 2025, the entire contents of which are incorporated herein by reference.

### FIELD

Embodiments described herein relate generally to a semiconductor device and a method of manufacturing a semiconductor device.

### BACKGROUND

A semiconductor device is known where one surface of a semiconductor chip is bonded to an electrode terminal such as a clip or a connector through a bonding material such as solder, and the other surface of the semiconductor chip is bonded to an electrode terminal such as a lead frame. When the corresponding semiconductor device is mounted on a printed circuit board by reflowing, a bonding material having a higher melting point than a reflow temperature (hereinafter, referred to as a first reflow temperature) in the corresponding reflowing needs to be used. Therefore, a reflow temperature at which the semiconductor chip and the electrode terminal are bonded through the corresponding bonding material by reflowing is higher than the first reflow temperature and may be a temperature of, for example, 300° C. or higher. As recognized by the present inventor, when the semiconductor chip and the electrode terminal are bonded by reflowing at a high temperature of higher than 300° C., warpage of the chip caused by thermal deformation may excessively increase. In this case, there is a concern that it is difficult to discharge voids formed by vaporization of a flux including the bonding material, water, and the like to the outside of the bonding material. When the voids remain in the bonding material, heat resistance between the semiconductor chip and the electrode terminal increases. Therefore, it is difficult to increase the amount of heat transmitted from the semiconductor chip to the electrode terminal. Accordingly, during an operation of the semiconductor device, there is a concern that the temperature of the semiconductor chip may excessively increase.

An example of related art includes JP-A-2023-138193.

### DESCRIPTION OF THE DRAWINGS

FIG. 1 is a cross-sectional view illustrating a semiconductor device according to a first embodiment.

FIG. 2 is a phase diagram illustrating a lead-tin binary alloy.

FIG. 3 is a cross-sectional view illustrating a semiconductor device according to Comparative Example.

FIG. 4 is a flowchart illustrating a method of manufacturing the semiconductor device according to Comparative Example.

FIG. 5 is a first cross-sectional view illustrating the method of manufacturing the semiconductor device according to Comparative Example.

FIG. 6 is a second cross-sectional view illustrating the method of manufacturing the semiconductor device according to Comparative Example.

FIG. 7 is a third cross-sectional view illustrating the method of manufacturing the semiconductor device according to Comparative Example.

FIG. 8 is a flowchart illustrating a method of manufacturing the semiconductor device according to the first embodiment.

FIG. 9 is a first cross-sectional view illustrating the method of manufacturing the semiconductor device according to the first embodiment.

FIG. 10 is a second cross-sectional view illustrating the method of manufacturing the semiconductor device according to the first embodiment.

FIG. 11 is a third cross-sectional view illustrating the method of manufacturing the semiconductor device according to the first embodiment.

FIG. 12 is a fourth cross-sectional view illustrating the method of manufacturing the semiconductor device according to the first embodiment.

FIG. 13 is a cross-sectional view illustrating a semiconductor device according to a second embodiment.

FIG. 14 is a flowchart illustrating a method of manufacturing the semiconductor device according to the second embodiment.

FIG. 15 is a first cross-sectional view illustrating the method of manufacturing the semiconductor device according to the second embodiment.

FIG. 16 is a second cross-sectional view illustrating the method of manufacturing the semiconductor device according to the second embodiment.

FIG. 17 is a third cross-sectional view illustrating the method of manufacturing the semiconductor device according to the second embodiment.

FIG. 18 is a fourth cross-sectional view illustrating the method of manufacturing the semiconductor device according to the second embodiment.

FIG. 19 is a cross-sectional view illustrating a semiconductor device according to a third embodiment.

FIG. 20 is a flowchart illustrating a method of manufacturing a semiconductor device according to the third embodiment.

FIG. 21 is a first cross-sectional view illustrating the method of manufacturing the semiconductor device according to the third embodiment.

FIG. 22 is a second cross-sectional view illustrating the method of manufacturing the semiconductor device according to the third embodiment.

FIG. 23 is a third cross-sectional view illustrating the method of manufacturing the semiconductor device according to the third embodiment.

FIG. 24 is a fourth cross-sectional view illustrating the method of manufacturing the semiconductor device according to the third embodiment.

### DETAILED DESCRIPTION

Embodiments provide a semiconductor device where an excessive increase in the temperature of a semiconductor chip can be prevented.

In general, according to one embodiment, a semiconductor device includes: a semiconductor chip having a first chip surface facing a first side of a first direction and having a second chip surface facing a second side of the first direction; a first electrode terminal facing the first chip surface in the first direction; a second electrode terminal facing the second chip surface in the first direction; and a bonding material configured to bond at least the semiconductor chip and each of the first electrode terminal and the second electrode terminal and formed of a solder. The bonding material includes a first bonding material and a second bonding material bonded to the first bonding material. The first bonding material includes a first bonding layer bonded to the first chip surface. The second bonding material includes a second bonding layer configured to bond the first bonding layer and the first electrode terminal. A proportion of weight of lead in the second bonding material is less than a proportion of weight of lead in the first bonding material.

According to another embodiment, provided is a method of manufacturing a semiconductor device including a semiconductor chip having a first chip surface facing a first side of a first direction and having a second chip surface facing a second side of the first direction, a first electrode terminal facing the first chip surface in the first direction, a second electrode terminal facing the second chip surface in the first direction, and a bonding material configured to bond at least the semiconductor chip and each of the first electrode terminal and the second electrode terminal and formed of a solder, the method including a bonding step of forming the bonding material. The bonding material includes a first bonding material and a second bonding material bonded to the first bonding material. A proportion of weight of lead in the second bonding material is less than a proportion of weight of lead in the first bonding material. The first bonding material includes a first bonding layer bonded to the first chip surface and a third bonding layer configured to bond the second chip surface and the second electrode terminal. The second bonding material includes a second bonding layer configured to bond the first bonding layer and the first electrode terminal. The bonding step includes a first reflow step of reflowing each of the first bonding layer provided on the first chip surface and the third bonding layer provided on the second chip surface, a second bonding material application step of applying the second bonding layer to the first bonding layer, a placement step of placing the first electrode terminal on the second bonding layer, and a second reflow step of reflowing the second bonding layer. A reflow temperature in the second reflow step is lower than a reflow temperature in the first reflow step.

Hereinafter, a semiconductor device according to an embodiment and a method of manufacturing the semiconductor device will be described with reference to the drawings.

A first direction D1 illustrated in each of the drawings is an up-down direction of the semiconductor device. A side (+D1 side) of the first direction D1 where an arrow faces is an upper side of the semiconductor device. A side (−D1 side) of the first direction D1 opposite to the side where arrow faces is a lower side of the semiconductor device. In the following description, the up-down direction of the semiconductor device will be referred to as “up-down direction” or “first direction D1”, the upper side of the semiconductor device will be referred to as “upper side” or “first side of the first direction D1”, and the lower side of the semiconductor device will be referred to as “lower side” or “second side of the first direction D1”.

A second direction D2 illustrated in each of the drawings is a direction perpendicular to the first direction D1. In the following description, a side (+D2 side) of the second direction D2 where an arrow faces will be referred to as “first side of the second direction D2”, and a side (−D2 side) of the second direction D2 opposite to the side where arrow faces will be referred to as “second side of the second direction D2”.

A third direction D3 illustrated in each of the drawings is a direction perpendicular to both of the first direction D1 and the second direction D2.

In the present specification, the terms “perpendicular”, “identical”, “same”, and the like and values of a length, an angle, and the like that specify a shape of each of portions forming a semiconductor device and the degree of a relative arrangement relationship between the portions are not limited to the exact meanings, and are interpreted to include a range where the same functions can be expected and a range of design tolerance. In addition, each of the drawings is schematic and conceptual, and a dimension between portions forming a semiconductor device, a dimensional ratio between the portions, and the like are not necessarily the same as the actual ones. Further, when the same portion is illustrated in different drawings, a dimension or a ratio of the portion may vary depending on the drawings.

### First Embodiment

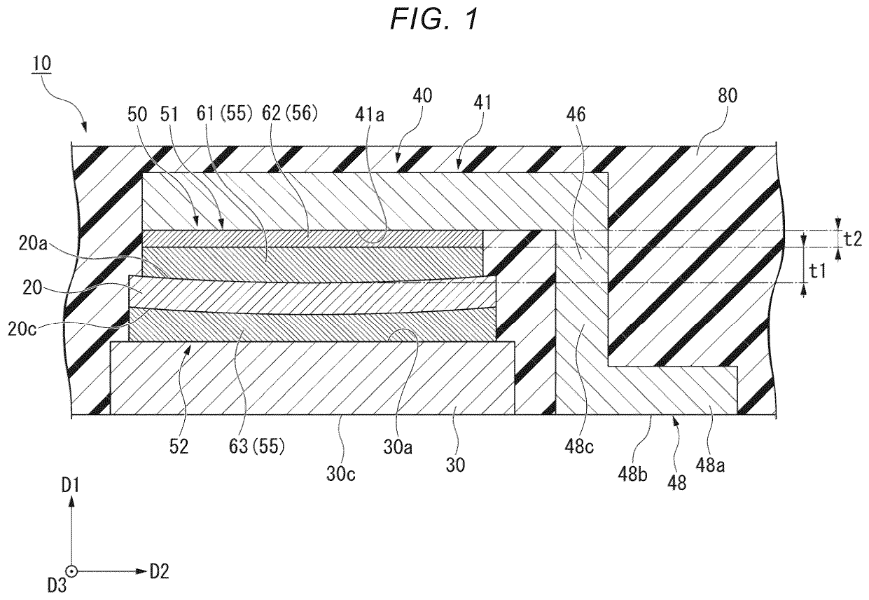

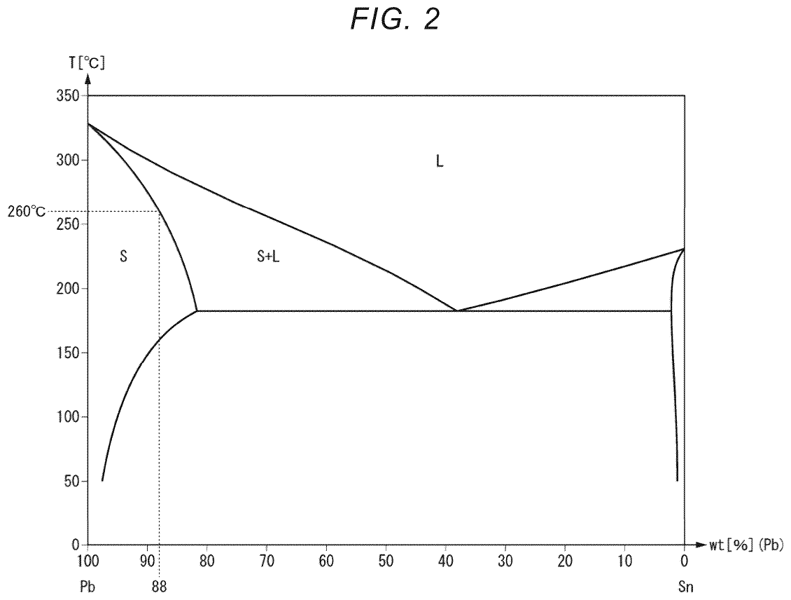

FIG. 1 is a cross-sectional view illustrating a semiconductor device 10 according to the present embodiment. FIG. 2 is a phase diagram illustrating a lead (Pb)-tin (Sn) binary alloy. The semiconductor device 10 according to the present embodiment is a semiconductor device such as a metal-oxide-semiconductor field-effect transistor (MOSFET) or an insulated gate bipolar transistor (IGBT). As illustrated in FIG. 1, the semiconductor device 10 includes a semiconductor chip 20, a first electrode terminal 40, a second electrode terminal 30, an external terminal 48, a bonding material 50, and a resin portion 80. In the present embodiment, the second electrode terminal 30 is, for example, a lead frame. In the present embodiment, the first electrode terminal 40 is, for example, a clip or a connector.

In the up-down direction, the semiconductor chip 20 is disposed between the second electrode terminal 30 and the first electrode terminal 40. The semiconductor chip 20 is disposed in the resin portion 80. The semiconductor chip 20 has a plate shape extending in a direction perpendicular to the up-down direction. A plate surface of the semiconductor chip 20 faces the up-down direction. The semiconductor chip 20 includes, for example, a substrate that is formed of a semiconductor material such as silicon, silicon carbide, gallium arsenide, or gallium nitride and an electrode that is formed on each of a surface of the substrate facing the upper side and a surface of the substrate facing the lower side. A plurality of electrodes insulated from each other are formed on the surface of the substrate facing the upper side, and the plurality of electrodes are a source electrode and a gate electrode. The electrode formed on the surface of the substrate facing the lower side is a drain electrode. The semiconductor chip 20 includes a first chip surface 20a and a second chip surface 20c. The configuration of the semiconductor chip 20 is not limited to the present embodiment. For example, the drain electrode may be formed on the surface of the substrate facing the upper side, and the source electrode and the gate electrode may be formed on the surface of the substrate facing the lower side.

The first chip surface 20a is a surface facing the upper side, that is, the first side (+D1 side) of the first direction D1 among outer surfaces of the semiconductor chip 20. Although not illustrated in the drawing, in the present embodiment, the first chip surface 20a includes surfaces of the substrate and the plurality of electrodes facing the upper side. The second chip surface 20c is a surface facing the lower side, that is, the second side (−D1 side) of the first direction D1 among the outer surfaces of the semiconductor chip 20. In the present embodiment, the second chip surface 20c includes surfaces of the substrate and the electrode facing the lower side.

The second electrode terminal 30 has a plate shape extending in the direction perpendicular to the up-down direction. A plate surface of the second electrode terminal 30 faces the up-down direction. The second electrode terminal 30 is disposed below the semiconductor chip 20.

The second electrode terminal 30 faces the second chip surface 20c in the up-down direction, that is, the first direction D1. In the present embodiment, a dimension in the second direction D2 and a dimension in the third direction D3 of the second electrode terminal 30 are more than a dimension in the second direction D2 and a dimension in the third direction D3 of the semiconductor chip 20, respectively. The second electrode terminal 30 has conductivity. In the present embodiment, the second electrode terminal 30 is formed of copper. The second electrode terminal 30 is manufactured, for example, by pressing a copper plate. The second electrode terminal 30 may be formed of another metal material such as silver or gold. The second electrode terminal 30 includes a second bonding surface 30a and a lower surface 30c. A portion of the second electrode terminal 30 other than the lower surface 30c is disposed in the resin portion 80. A portion of a side surface of the second electrode terminal 30 may be exposed from the resin portion 80 by cutting or the like. In addition, the lower surface 30c is connected to an electrode in a printed circuit board (not illustrated) through a solder. Therefore, the lower surface 30c may be covered with a tin-based solder layer, a tin-silver-copper (Sn—Ag—Cu)-based solder layer, and the like.

The second bonding surface 30a is a surface facing the upper side among outer surfaces of the second electrode terminal 30. The second bonding surface 30a is bonded to the second chip surface 20c through a second bonding portion 52 in the bonding material 50. As a result, the second electrode terminal 30 and the semiconductor chip 20 are bonded. The second bonding portion 52 has conductivity. Therefore, the second electrode terminal 30 and the semiconductor chip 20 are electrically connected through the second bonding portion 52. The lower surface 30c is a surface facing the lower side among the outer surfaces of the second electrode terminal 30. The lower surface 30c is exposed from the resin portion 80 to the lower side.

The first electrode terminal 40 is an electrode terminal electrically connected to the first chip surface 20a. The first electrode terminal 40 is disposed in the resin portion 80. The first electrode terminal 40 has conductivity. In the present embodiment, the first electrode terminal 40 is formed of copper. The first electrode terminal 40 is manufactured, for example, by pressing a copper plate. The first electrode terminal 40 may be formed of another metal material such as silver or gold. The first electrode terminal 40 includes a to-be-bonded portion 41 and a first connection portion 46.

The to-be-bonded portion 41 has a plate shape extending in the direction perpendicular to the up-down direction. A plate surface of the to-be-bonded portion 41 faces the up-down direction. The to-be-bonded portion 41 is positioned over the semiconductor chip 20. The to-be-bonded portion 41 faces the first chip surface 20a in the up-down direction, that is, the first direction D1. As a result, the first electrode terminal 40 faces the first chip surface 20a in the up-down direction, that is, the first direction D1. The to-be-bonded portion 41 extends in the second direction D2. An end portion of the to-be-bonded portion 41 on the first side (+D2 side) of the second direction D2 is positioned on the first side of the second direction D2 further than the semiconductor chip 20 and the second electrode terminal 30. The to-be-bonded portion 41 includes a first bonding surface 41a.

The first bonding surface 41a is a surface facing the lower side among outer surfaces of the to-be-bonded portion 41. The first bonding surface 41a is bonded to the first chip surface 20a through a first bonding portion 51 in the bonding material 50. As a result, the first electrode terminal 40 and the semiconductor chip 20 are bonded. The first bonding portion 51 has conductivity. Therefore, the first electrode terminal 40 and the semiconductor chip 20 are electrically connected through the first bonding portion 51.

The first connection portion 46 has a plate shape protruding from an end portion of the to-be-bonded portion 41 on the first side (+D2 side) of the second direction D2 to the lower side. A plate surface of the first connection portion 46 faces the second direction D2. The first connection portion 46 may have a plate shape positioned on the lower side toward the first side of the second direction D2. An end portion of the first connection portion 46 on the upper side is connected to an end portion of the to-be-bonded portion 41 on the first side of the second direction D2.

The external terminal 48 is disposed on the first side (+D2 side) of the second direction D2 further than the semiconductor chip 20 and the second electrode terminal 30. The external terminal 48 is spaced from the second electrode terminal 30 in the second direction D2. In the present embodiment, the external terminal 48 is, for example, a source terminal used for connection to the outside of the semiconductor device 10. The external terminal 48 has conductivity. The external terminal 48 is formed of a metal. The external terminal 48 includes a terminal portion 48a and a second connection portion 48c.

The terminal portion 48a has a plate shape extending in the direction perpendicular to the up-down direction. A plate surface of the terminal portion 48a faces the up-down direction. A portion of the terminal portion 48a other than a lower surface 48b that is a surface facing the lower side is disposed in the resin portion 80. The lower surface 48b is exposed from the resin portion 80 to the lower side. A portion of a side surface of the terminal portion 48a may be exposed from the resin portion 80 by cutting or the like. In addition, the lower surface 48b is connected to an electrode in a printed circuit board (not illustrated) through a solder. Therefore, the lower surface 48b may be covered with a tin-based solder layer, a tin-silver-copper (Sn—Ag—Cu)-based solder layer, and the like.

The second connection portion 48c has a plate shape protruding from an end portion of the terminal portion 48a on the second side (−D2 side) of the second direction D2 to the upper side. A plate surface of the second connection portion 48c faces the second direction D2. An end portion of the second connection portion 48c on the lower side is connected to an end portion of the terminal portion 48a on the second side of the second direction D2. An end portion of the second connection portion 48c on the upper side is connected to an end portion of the first connection portion 46 on the lower side. As a result, the first electrode terminal 40 and the external terminal 48 are electrically connected. In the present embodiment, the first electrode terminal 40 and the external terminal 48 are a part of the same member. The first electrode terminal 40 and the external terminal 48 may be different members. in this case, the first electrode terminal 40 and the external terminal 48 are bonded through a bonding material (not illustrated) to be electrically connected. As described above, the first electrode terminal 40 is electrically connected to the semiconductor chip 20. Accordingly, the semiconductor chip 20 is electrically connected to the external terminal 48.

In the present embodiment, the bonding material 50 bonds the semiconductor chip 20 and each of the first electrode terminal 40 and the second electrode terminal 30. That is, in the present embodiment, the bonding material 50 bonds at least the semiconductor chip 20 and each of the first electrode terminal 40, and the second electrode terminal 30. The bonding material 50 is formed of a solder. The bonding material 50 has conductivity. In the present embodiment, the bonding material 50 includes the first bonding portion 51 and the second bonding portion 52. In addition, the bonding material 50 includes a first bonding material 55 and a second bonding material 56.

In the up-down direction, the first bonding portion 51 is positioned between the semiconductor chip 20 and the to-be-bonded portion 41. The first bonding portion 51 bonds the first chip surface 20a and the first bonding surface 41a. That is, the first bonding portion 51 bonds the semiconductor chip 20 and the first electrode terminal 40.

As a result, the semiconductor chip 20 and the first electrode terminal 40 are electrically connected through the first bonding portion 51.

In the up-down direction, the second bonding portion 52 is positioned between the semiconductor chip 20 and the second electrode terminal 30. The second bonding portion 52 bonds the second chip surface 20c and the second bonding surface 30a. That is, the second bonding portion 52 bonds the semiconductor chip 20 and the second electrode terminal 30. As a result, the semiconductor chip 20 and the second electrode terminal 30 are electrically connected through the second bonding portion 52.

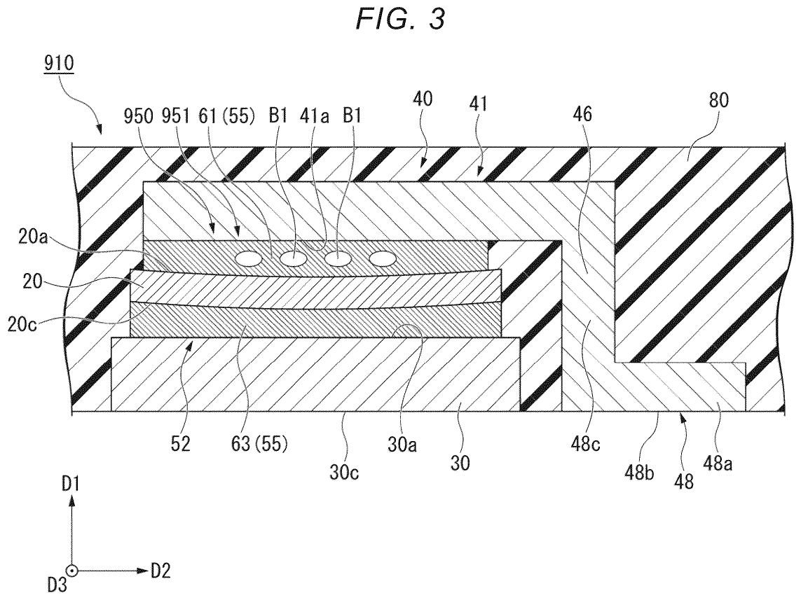

Each of the first bonding material 55 and the second bonding material 56 is formed of a solder. The first bonding material 55 is an alloy including a metal such as tin or lead. In the present embodiment, a first proportion R1 that is a proportion of weight of lead in the first bonding material 55 is 92% or more and 99% or less. Therefore, as illustrated in FIG. 2, a melting point of the first bonding material 55 is 275° C. or higher. Each of tin and lead in the first bonding material 55 may be distributed in clumps. The first proportion R1 in the present embodiment is the proportion of weight of lead in the entire first bonding material 55. In addition, the melting point of the first bonding material 55 in the present embodiment is a solidus temperature among endothermic peaks obtained by differential thermal analysis or the like. In the present embodiment, the first bonding material 55 includes silver. Therefore, in the present embodiment, the strength of the first bonding material 55 can be improved. In the present embodiment, a third t proportion R3 that is a proportion of weight of silver in the first bonding material 55 is 1.0% or more and 3.5% or less. The first bonding material 55 does not need to include silver. As described below, in a first reflow step P012 (refer to FIG. 3), the first bonding material 55 is formed by solidifying the liquid first bonding material 55 that is melted by reflowing the paste-like first bonding material 55. As illustrated in FIG. 1, in the present embodiment, the first bonding material 55 includes a first bonding layer 61 and a third bonding layer 63.

The second bonding material 56 is an alloy including a metal such as tin or lead. In the present embodiment, a second proportion R2 that is a proportion of weight of lead in the second bonding material 56 is 88% or more and 92% or less. Therefore, as illustrated in FIG. 2, a melting point of the second bonding material 56 is 260° C. or higher. The second proportion R2 is less than the first proportion R1. That is, in the present embodiment, the proportion of weight of lead in the second bonding material 56 is less than the proportion of weight of lead in the first bonding material 55. As described below, in a second reflow step P015 (refer to FIG. 3), the second bonding material 56 is formed by solidifying the liquid second bonding material 56 that is melted by reflowing the paste-like second bonding material 56. Each of tin and lead in the second bonding material 56 may be distributed in clumps. The second proportion R2 in the present embodiment is the proportion of weight of lead in the entire second bonding material 56. In addition, the melting point of the second bonding material 56 in the present embodiment is a solidus temperature among endothermic peaks obtained by differential thermal analysis or the like. Further, the second proportion R2 is the proportion of weight of lead in the second bonding material 56 after the second reflow step described below. A proportion of weight of lead in the second bonding material 56 before the second reflow step may be less than the second proportion R2.

In the present embodiment, the second bonding material 56 includes silver. A fourth proportion R4 that is a proportion of weight of silver in the second bonding material 56 is, for example, 1.5% or less. The fourth proportion R4 is less than the third proportion R3. That is, the proportion of weight of silver in the first bonding material 55 is more than the proportion of weight of silver in the second bonding material 56. The second bonding material 56 does not need to include silver.

In the present embodiment, the second bonding material 56 includes at least one of bismuth and indium. As a result, the melting point of the paste-like second bonding material 56 can be reduced. Therefore, an excessive increase in second reflow temperature T2 in the second reflow step P015 can be prevented. The second bonding material 56 does not need to include bismuth and indium. As illustrated in FIG. 1, in the present embodiment, the second bonding material 56 includes a second bonding layer 62.

In the present embodiment, the first bonding portion 51 includes the first bonding layer 61 and the second bonding layer 62. The second bonding layer 62 is positioned over the first bonding layer 61. In the up-down direction, the first bonding layer 61 is disposed between the semiconductor chip 20 and the second bonding layer 62. The first bonding layer 61 is bonded to the first chip surface 20a of the semiconductor chip 20. In the up-down direction, the second bonding layer 62 is disposed between the first bonding layer 61 and the to-be-bonded portion 41. In the present embodiment, the second bonding layer 62 is bonded to the first bonding layer 61 and the first bonding surface 41a. As a result, the second bonding layer 62 bonds the first bonding layer 61 and the first electrode terminal 40. That is, the second bonding material 56 is bonded to the first bonding material 55. As a result, the first bonding portion 51 bonds the semiconductor chip 20 and the first electrode terminal 40.

In the present embodiment, a thickness t1 of the first bonding layer 61 is about 25 μm, and a thickness t2 of the second bonding layer 62 is about 5 μm. The thickness t2 of the second bonding layer 62 is less than the thickness t1 of the first bonding layer 61. The thickness t2 of the second bonding layer 62 may be more than the thickness t1 of the first bonding layer 61, or may be the same as the thickness t1 of the first bonding layer 61. Each of the thickness t1 of the first bonding layer 61 and the thickness t2 of the second bonding layer 62 is not limited to the present embodiment.

In the present embodiment, the second bonding portion 52 includes the third bonding layer 63. In the up-down direction, the third bonding layer 63 is disposed between the semiconductor chip 20 and the second electrode terminal 30. The third bonding layer 63 is bonded to the second chip surface 20c and the second bonding surface 30a. That is, the third bonding layer 63 bonds the second chip surface 20c and the second electrode terminal 30. As a result, the second bonding portion 52 bonds the semiconductor chip 20 and the second electrode terminal 30. In the present embodiment, a thickness of the third bonding layer 63 is about 25 μm. The thickness of the third bonding layer 63 is not limited to the present embodiment.

Although not illustrated in the drawing, the semiconductor device 10 according to the present embodiment is mounted on a printed circuit board (not illustrated) by reflowing in a mounting step Pm. In the present embodiment, a reflow temperature Tm in the mounting step Pm is about 250° C. As described above, in the present embodiment, the melting point of the first bonding material 55 is 275° C. or higher, and the melting point of the second bonding material 56 is 260° C. or higher. Accordingly, in the mounting step Pm, the melting of the bonding material 50 can be suitably prevented. In the mounting step Pm, a decrease in the bonding strength between the semiconductor chip 20 and each of the first electrode terminal 40 and the second electrode terminal 30 can be prevented.

The resin portion 80 covers the semiconductor chip 20, the portion of the second electrode terminal 30 other than the lower surface 30c, the first electrode terminal 40, and a portion of the external terminal 48 other than the lower surface 48b. The resin portion 80 is bonded and fixed to the semiconductor chip 20, the portion of the second electrode terminal 30 other than the lower surface 30c, the first electrode terminal 40, and the portion of the external terminal 48 other than the lower surface 48b. The resin portion 80 insulates the units forming the semiconductor device 10 from each other. In addition, the resin portion 80 seals each of the units forming the semiconductor device 10 from external air. As a result, deterioration of each of the units forming the semiconductor device 10 by corrosion or the like can be prevented. As the resin portion 80, for example, a well-known epoxy resin, an UV-curable resin, a thermosetting resin, or the like may be used. However, the resin portion 80 is not limited to this example. In the present embodiment, the resin portion 80 is formed of an epoxy resin.

FIG. 3 is a cross-sectional view illustrating a semiconductor device 910 according to Comparative Example. Next, the semiconductor device 910 according to Comparative Example will be described. In the following description, components according to the same aspect as that of the semiconductor device 10 according to the present embodiment described above will be represented by the same reference numerals, and the description thereof will not be repeated. The semiconductor device 910 according to Comparative Example includes the semiconductor chip 20, the first electrode terminal 40, the second electrode terminal 30, the external terminal 48, a bonding material 950, and the resin portion 80.

The bonding material 950 bonds the semiconductor chip 20 and each of the first electrode terminal 40 and the second electrode terminal 30. The bonding material 950 includes a first bonding portion 951 and the second bonding portion 52. The bonding material 950 according to Comparative Example includes only the first bonding material 55. That is, the bonding material 950 according to Comparative Example does not include the second bonding material 56. The configuration and the like of each of the second bonding portion 52 and the first bonding material 55 according to Comparative example are the same as the configuration and the like of each of the second bonding portion 52 and the first bonding material 55 according to the present embodiment.

In the up-down direction, the first bonding portion 951 is positioned between the semiconductor chip 20 and the to-be-bonded portion 41. The first bonding portion 951 bonds the first chip surface 20a and the first bonding surface 41a. In the semiconductor device 910 according to Comparative Example, the first bonding material 55 includes the first bonding layer 61 and the third bonding layer 63.

In the semiconductor device 910 according to Comparative Example, the first bonding portion 951 includes only the first bonding layer 61. The first bonding layer 61 is bonded to the first chip surface 20a of the semiconductor chip 20 and the first bonding surface 41a. As a result, the first bonding portion 951 bonds the semiconductor chip 20 and the first electrode terminal 40.

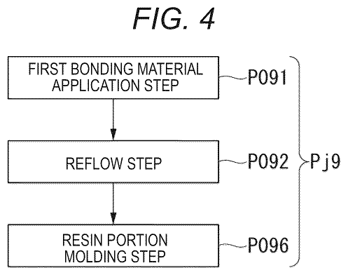

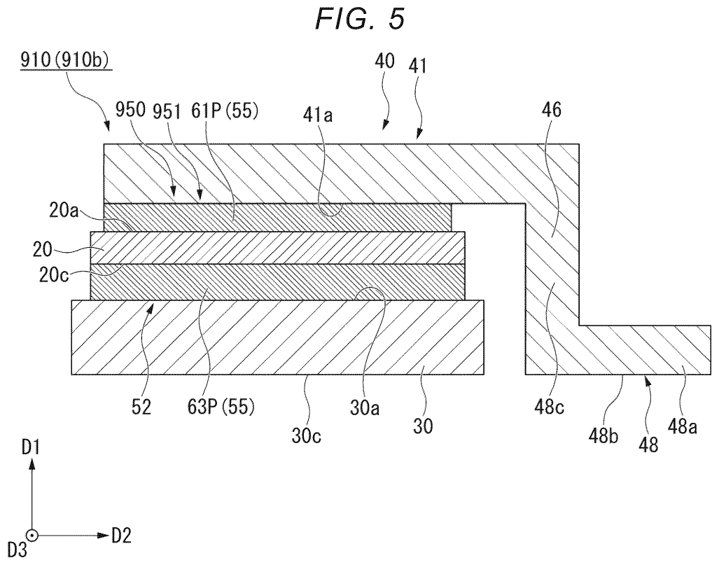

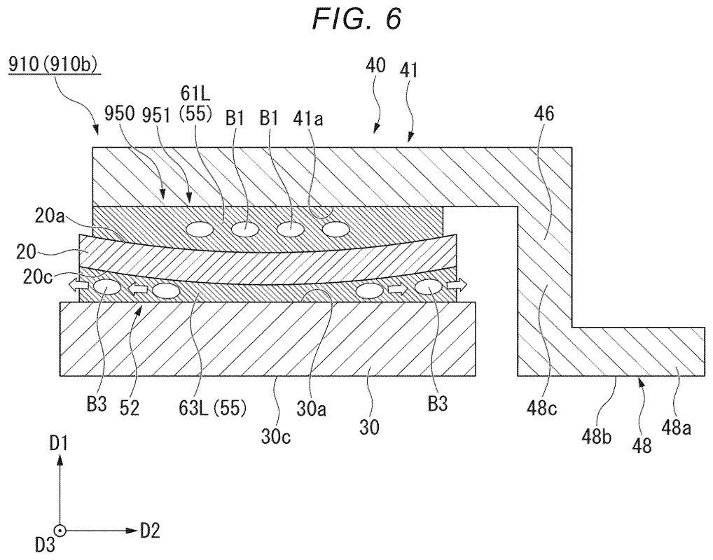

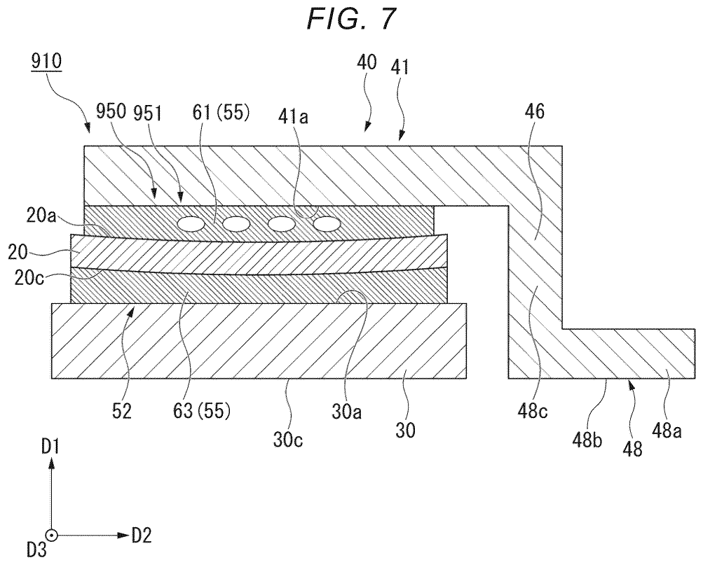

FIG. 4 is a flowchart illustrating a method of manufacturing the semiconductor device 910 according to Comparative Example. FIG. 5 is a first cross-sectional view illustrating the method of manufacturing the semiconductor device 910 according to Comparative Example. FIG. 6 is a second cross-sectional view illustrating the method of manufacturing the semiconductor device 910 according to Comparative Example. FIG. 7 is a third cross-sectional view illustrating the method of manufacturing the semiconductor device 910 according to Comparative Example. Next, the method of manufacturing the semiconductor device 910 according to Comparative Example will be described. As illustrated in FIG. 4, the method of manufacturing the semiconductor device 910 according to Comparative Example includes a bonding step Pj9 of forming the bonding material 950. The bonding step Pj9 includes a first bonding material application step P091 of applying a paste-like first bonding layer 61P and a paste-like third bonding layer 63P to the first chip surface 20a and the second chip surface 20c of the semiconductor chip 20, respectively, a reflow step P092 of reflowing each of the first bonding layer 61P provided on the first chip surface 20a and the third bonding layer 63P provided on the second chip surface 20c, and a resin portion molding step P096 of molding the resin portion 80. In the following description, an operator and the like include an operator, an assembly device, and the like that perform the operation of each of the steps. The operation of each of the steps may be performed by only the operator, may be performed by only the assembly device, or may be performed by the operator and the assembly device.

In the first bonding material application step P091, first, as illustrated in FIG. 5, the operator and the like apply the paste-like third bonding layer 63P to the second bonding surface 30a of the second electrode terminal 30. Next, the operator and the like place the semiconductor chip 20 on the third bonding layer 63P. As a result, the third bonding layer 63P is in contact with each of the second chip surface 20c and the second bonding surface 30a. Next, the operator and the like apply the paste-like first bonding layer 61P to the first chip surface 20a of the semiconductor chip 20. Next, the operator and the like place the first electrode terminal 40 on the first bonding layer 61P. As a result, the first bonding layer 61P is in contact with each of the first chip surface 20a and the first bonding surface 41a. When the operator and the like place the first electrode terminal 40 on the first bonding layer 61P, the first bonding material application step P091 ends. In the semiconductor device 910 according to Comparative Example, each of a thickness of the first bonding layer 61P and a thickness of the third bonding layer 63 is about 25 μm. In the following description, the semiconductor device 910 according to Comparative Example when the first bonding material application step P091 ends will also be referred to as a semiconductor device 910b before bonding.

Each of the first bonding layer 61P and the third bonding layer 63P includes a flux. In the present embodiment, the flux is, for example, rosin. The flux functions to improve the wettability of the semiconductor chip 20, the second electrode terminal 30, the first electrode terminal 40, and a liquid first bonding layer 61L and a liquid third bonding layer 63L that are melted.

In the reflow step P092, the operator and the like reflow each of the first bonding layer 61P and the third bonding layer 63P. As a result, the semiconductor chip 20 and each of the first electrode terminal 40 and the second electrode terminal 30 are bonded. In the reflow step P092, the operator and the like heat the semiconductor device 910b before bonding in a heating furnace (not illustrated), for example, in a vacuum to melt each of the paste-like first bonding layer 61P and the paste-like third bonding layer 63P. Next, the operator and the like take out the semiconductor device 910b before bonding from the heating furnace for cooling to solidify the liquid first bonding layer 61L and the liquid third bonding layer 63L.

As described above, the melting point of the first bonding material 55 is 275° C. or higher. In order to improve the bonding strength between the semiconductor chip 20 and each of the first electrode terminal 40 and the second electrode terminal 30, in the reflow step P092, the entirety of each of the first bonding layer 61P and the third bonding layer 63P needs to be melted. Accordingly, a reflow temperature Tr in the reflow step P092 is set to about 350° C. As illustrated in FIG. 6, in the reflow step P092, when the temperature of the semiconductor chip 20 increases, warpage of the semiconductor chip 20 increases due to thermal expansion. Due to the thermal expansion, the semiconductor chip 20 according to the present embodiment is warped such that a center portion in the second direction D2 and a center portion in the third direction D3 are convex to the lower side. When the temperature of the semiconductor chip 20 exceeds 300° C., the warpage of the semiconductor chip 20 is about 50 μm. As described above, the thickness of the first bonding layer 61P is about 25 um. Therefore, when the temperature of the semiconductor chip 20 exceeds 300° C., a gap in the up-down direction between each of an end portion of the semiconductor chip 20 in the second direction D2 and an end portion of the semiconductor chip 20 in the third direction D3 and the to-be-bonded portion 41 is excessively narrow.

In the reflow step P092, when the flux (not illustrated), water, and the like in the paste-like first bonding layer 61P are vaporized, a void B1 that is a gap in the liquid first bonding layer 61L is formed. In the reflow step P092, when the flux (not illustrated), water, and the like in the paste-like third bonding layer 63P are vaporized, a void B3 that is a gap in the liquid third bonding layer 63L is formed. The gap in the up-down direction between each of the end portion of the semiconductor chip 20 in the second direction D2 and the end portion of the semiconductor chip 20 in the third direction D3 and the second electrode terminal 30 is wide. Therefore, the void B3 is discharged from an end portion of the third bonding layer 63L to the outside of the third bonding layer 63L. However, as described above, due to the warpage of the semiconductor chip 20, the gap in the up-down direction between each of the end portion of the semiconductor chip 20 in the second direction D2 and the end portion of the semiconductor chip 20 in the third direction D3 and the to-be-bonded portion 41 is excessively narrow. Therefore, it is difficult to discharge the void B1 from the end portion of the third bonding layer 63L to the outside of the third bonding layer 63L. Therefore, in the semiconductor device 910 according to Comparative example, when the semiconductor device 910b before bonding is taken out from the heating furnace for cooling to solidify the liquid first bonding layer 61L and the liquid third bonding layer 63L, as illustrated in FIG. 7, a large amount of the voids B1 remain in the first bonding layer 61. When the operator and the like solidify the liquid first bonding layer 61L and the liquid third bonding layer 63L to form the bonding material 950, the reflow step P092 ends.

In the resin portion molding step P096, the operator and the like form the resin portion 80. In the present embodiment, using a molding method such as transfer molding, as illustrated in FIG. 3, the semiconductor chip 20, the portion of the second electrode terminal 30 other than the lower surface 30c, the first electrode terminal 40, and the portion of the external terminal 48 other than the lower surface 48b are covered with the resin portion 80, and the resin portion 80 is cured, for example, by heating to mold the resin portion 80. When the operator and the like mold the resin portion 80, the resin portion molding step P096 ends. When the resin portion molding step P096 ends, the bonding step Pj9 ends, and the semiconductor device 910 illustrated in FIG. 3 is manufactured.

As described above, since the void B1 is a gap, a thermal conductivity of the void B1 is less than a thermal conductivity of a solder. Accordingly, when a large amount of the voids B1 remain in the first bonding layer 61, a heat resistance between the semiconductor chip 20 and the first electrode terminal 40 increases. Therefore, during the operation of the semiconductor device 910, the amount of heat transmitted from the semiconductor device 910 to the first electrode terminal 40 decreases. Accordingly, in the semiconductor device 910 according to Comparative example, during the operation of the semiconductor device 910, there is a concern that the temperature of the semiconductor device 910 may excessively increase.

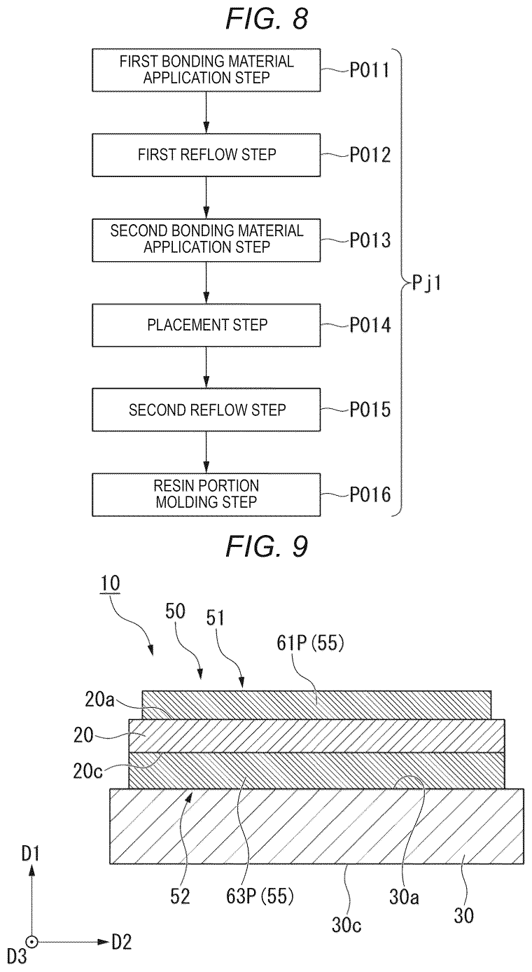

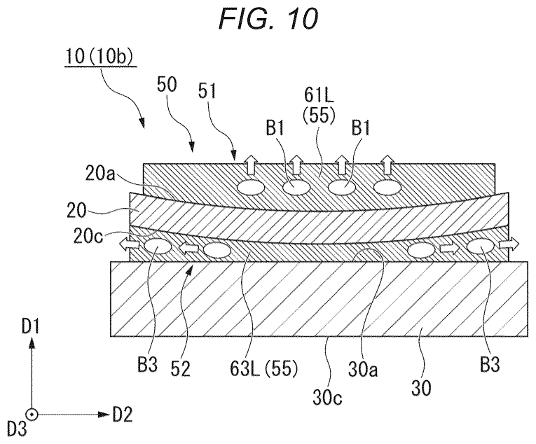

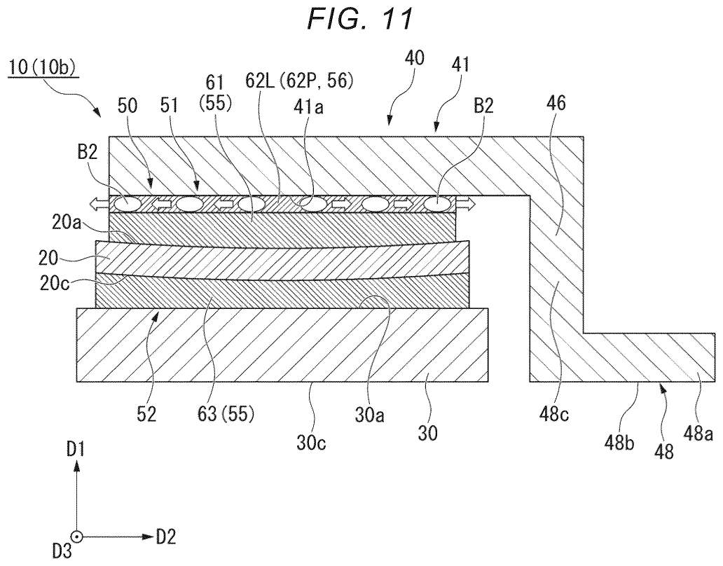

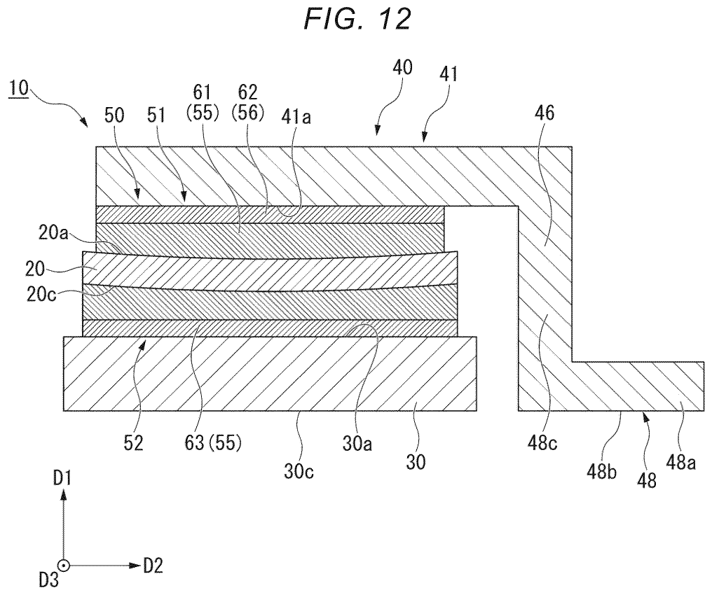

FIG. 8 is a flowchart illustrating a method of manufacturing the semiconductor device 10 according to the present embodiment. FIG. 9 is a first cross-sectional view illustrating the method of manufacturing the semiconductor device 10 according to the present embodiment. FIG. 10 is a second cross-sectional view illustrating the method of manufacturing the semiconductor device 10 according to the present embodiment. FIG. 11 is a third cross-sectional view illustrating the method of manufacturing the semiconductor device 10 according to the present embodiment. FIG. 12 is a fourth cross-sectional view illustrating the method of manufacturing the semiconductor device 10 according to the present embodiment. Next, the method of manufacturing the semiconductor device 10 according to the present embodiment will be described. As illustrated in FIG. 8, the method of manufacturing the semiconductor device 10 according to the present embodiment includes a bonding step Pj1 of forming the bonding material 50. The bonding step Pj1 includes a bonding material application step P011 of applying a paste-like first bonding layer 61P and a paste-like third bonding layer 63P to the first chip surface 20a and the second chip surface 20c of the semiconductor chip 20, respectively, a first reflow step P012 of reflowing each of the first bonding layer 61P provided on the first chip surface 20a and the third bonding layer 63P provided on the second chip surface 20c, a second bonding material application step P013 of applying the paste-like second bonding layer 62P to the first bonding layer 61, a placement step P014 of placing the first electrode terminal 40 on the second bonding layer 62P, a second reflow step P015 of reflowing the second bonding layer 62P, and a resin portion molding step P016 of molding the resin portion 80.

In the first bonding material application step P011, first, as illustrated in FIG. 9, the operator and the like apply the paste-like third bonding layer 63P to the second bonding surface 30a of the second electrode terminal 30. Next, the operator and the like place the semiconductor chip 20 on the third bonding layer 63P. As a result, the third bonding layer 63P is in contact with each of the second chip surface 20c and the second bonding surface 30a. Next, the operator and the like apply the paste-like first bonding layer 61P to the first chip surface 20a of the semiconductor chip 20. As a result, the first bonding layer 61P is provided on the first chip surface 20a, and the third bonding layer 63P is provided on the second chip surface 20c. The first bonding layer 61P is opened to the upper side. When the operator and the like apply the first bonding layer 61P to the first chip surface 20a, the first bonding material application step P011 ends. As described above, the first proportion R1 that is the proportion of weight of lead in the first bonding material 55 is 92% or more and 99% or less. In the present embodiment, the first proportion R1 is about 95%. In addition, the third proportion R3 that is the proportion of weight of silver in the first bonding material 55 is about 1.5%, and the proportion of weight of tin is about 3.5%.

In the first reflow step P012, each of the first bonding layer 61P provided on the first chip surface 20a and the third bonding layer 63P provided on the second chip surface 20c is reflowed. As a result, the semiconductor chip 20 and the second electrode terminal 30 are bonded. In the first reflow step P012, the operator and the like heat the second electrode terminal 30 on which the semiconductor chip 20 is placed in a heating furnace (not illustrated), for example, in a vacuum to melt each of the paste-like first bonding layer 61P and the paste-like third bonding layer 63P. Next, the operator and the like take out the second electrode terminal 30 from the heating furnace for cooling to solidify the liquid first bonding layer 61L and the liquid third bonding layer 63L.

As described above, the melting point of the first bonding material 55 is 275° C. or higher. Therefore, a first reflow temperature T1 that is the reflow temperature in the first reflow step P012 is set to about 350° C. As in the semiconductor device 910 according to Comparative Example, as illustrated in FIG. 10, in the first reflow step P012, when the temperature of the semiconductor chip 20 increases, due to the thermal expansion, the semiconductor chip 20 is warped such that a center portion in the second direction D2 and a center portion in the third direction D3 are convex to the lower side. When the temperature of the semiconductor chip 20 exceeds 300° C., the warpage of the semiconductor chip 20 is about 50 μm.

In the first reflow step P012, the void B3 formed in the liquid third bonding layer 63L is discharged from the end portion of the third bonding layer 63L to the outside of the third bonding layer 63L. In addition, as described above, the first bonding layer 61P is opened to the upper side. Therefore, in the first reflow step P012 according to the present embodiment, even when the warpage of the semiconductor chip 20 increases, the void B1 formed in the liquid first bonding layer 61L is discharged from an upper end of the first bonding layer 61L to the outside of the first bonding layer 61L. As a result, in the bonding step Pj1 according to the present embodiment, when the second electrode terminal 30 is taken out from the heating furnace for cooling to solidify the liquid first bonding layer 61L and the liquid third bonding layer 63L, as illustrated in FIG. 11, the void B1 and the void B3 can be prevented from remaining in the first bonding layer 61 and the third bonding layer 63, respectively. When the operator and the like solidify the liquid first bonding layer 61L and the liquid third bonding layer 63L, the first reflow step P012 ends. At this time, the semiconductor chip 20 is bonded to the second electrode terminal 30 through the second bonding portion 52.

In the second bonding material application step P013, the paste-like second bonding layer 62P is applied to the first bonding layer 61. As illustrated in FIG. 11, the operator and the like apply the paste-like second bonding layer 62P to the first bonding layer 61. As a result, the second bonding layer 62P is provided on the first bonding layer 61. In the present embodiment, the melting point of the paste-like second bonding layer 62P is preferably 180° C. or higher and 220° C. or lower. In the present embodiment, the melting point of the second bonding layer 62P is about 183° C. As the second bonding layer 62P, for example, a solder (Sn37Pb) where the weight of lead in the second bonding layer 62P is about 37% or a lead-free solder (Sn3Ag) where the weight of lead in the second bonding layer 62P is about 3% may be used. In addition, as described above, the second bonding layer 62P includes at least one of bismuth and indium. In the present embodiment, the second bonding layer 62P includes bismuth. As a result, the melting point of the second bonding layer 62P can be suitably reduced. The second bonding layer 62P may include indium. When the operator and the like apply the second bonding layer 62P to the first bonding layer 61, the second bonding material application step P013 ends.

In the placement step P014, the first electrode terminal 40 is placed on the second bonding layer 62P. More specifically, the operator and the like place the to-be-bonded portion 41 on the second bonding layer 62P. As a result, the second bonding layer 62P is in contact with each of the first bonding layer 61 and the first bonding surface 41a. When the operator and the like place the first electrode terminal 40 on the second bonding layer 62P, the placement step P014 ends. In the following description, the semiconductor device 10 when the placement step P014 ends will also be referred to as a semiconductor device 10b before bonding.

In the second reflow step P015, the second bonding layer 62P is reflowed. The operator and the like heat the semiconductor device 10b before bonding in a heating furnace (not illustrated), for example, in a vacuum to melt the paste-like second bonding layer 62P. Next, the operator and the like take out the semiconductor device 10b before bonding from the heating furnace for cooling to solidify the liquid second bonding layer 62L.

As described above, the melting point of the second bonding layer 62P is about 183° C. Therefore, in the present embodiment, the second reflow temperature T2 that is the reflow temperature in the second reflow step P015 is set to about 200° C. As described above, the first reflow temperature T1 is about 350° C. Accordingly, the reflow temperature in the second reflow step P015 is lower than the reflow temperature in the first reflow step P012. In the present embodiment, a reflow time in the second reflow step P015 is set to a long time of about 4 hours. As a result, in the second reflow step P015, the entire second bonding layer 62P can be melted. The reflow time is not limited to the present embodiment, and may be 3 hours or shorter or may be 5 hours or longer. As described above, the melting point of the first bonding material 55 is 275° C. or higher. Therefore, in the second reflow step P015, the melting of each of the first bonding layer 61 and the third bonding layer 63 can be prevented. As a result, in the second reflow step P015, the formation of voids in each of the first bonding layer 61 and the third bonding layer 63 can be prevented.

As described above, the second reflow temperature T2 is a low temperature of about 200° C. Therefore, as illustrated in FIG. 11, the warpage of the semiconductor chip 20 in the second reflow step P015 can be reduced. In the present embodiment, the warpage of the semiconductor chip 20 in the second reflow step P015 is about 30 μm. Therefore, the gap in the up-down direction between each of an end portion of the semiconductor chip 20 in the second direction D2 and the end portion of the semiconductor chip 20 in the third direction D3 and the to-be-bonded portion 41 can be prevented from being excessively narrow. Accordingly, in the second reflow step P015, a void B2 formed in the liquid second bonding layer 62L is discharged from an end portion of the second bonding layer 62L to the outside of the second bonding layer 62L. As a result, in the bonding step Pj1 according to the present embodiment, when the semiconductor device 10b before bonding is taken out from the heating furnace for cooling to solidify the liquid second bonding layer 62L, as illustrated in FIG. 12, the remaining of the void B2 in the second bonding layer 62 can be prevented. In addition, as described above, in the second reflow step P015, the formation of voids in each of the first bonding layer 61 and the third bonding layer 63 can be prevented. As a result, in the present embodiment, the remaining of voids in the bonding material 50 can be prevented.

In the second reflow step P015, the first bonding layer 61 is heated to the second reflow temperature T2. Therefore, a part of lead atoms in the first bonding layer 61 is diffused to the liquid second bonding layer 62L. As a result, the proportion of weight of lead in the liquid second bonding layer 62L can be increased. As described above, the reflow time in the second reflow step P015 of the present embodiment is set to a long time of about 4 hours. As a result, at a timing at which the second reflow step P015 ends, the second proportion R2 in the second bonding layer 62 can be increased to 88% or more and 92% or less. Accordingly, the melting point of the second bonding layer 62 can be increased to 260° C. or higher. As described above, the melting point of the first bonding material 55 is 275° C. or higher. Accordingly, as described above, the melting of the second bonding layer 62 by reflowing in the mounting step Pm of mounting the semiconductor device 10 on a printed circuit board (not illustrated) can be suitably prevented. Therefore, in the mounting step Pm, a decrease in the bonding strength between the semiconductor chip 20 and each of the first electrode terminal 40 and the second electrode terminal 30 can be prevented. When the operator and the like solidify the liquid second bonding layer 62L, the second reflow step P015 ends.

In the resin portion molding step P016, the operator and the like form the resin portion 80. The resin portion molding step P016 according to the present embodiment is the same as the resin portion molding step P096 according to Comparative Example described above. As illustrated in FIG. 1, the resin portion 80 is bonded and fixed to the semiconductor chip 20, the portion of the second electrode terminal 30 other than the lower surface 30c, the first electrode terminal 40, and the portion of the external terminal 48 other than the lower surface 48b. When the operator and the like mold the resin portion 80, the resin portion molding step P016 ends. When the resin portion molding step P016 ends, the bonding step Pj1 of the semiconductor device 10 ends, and the semiconductor device 10 illustrated in FIG. 1 is manufactured.

As described above, in the semiconductor device 10 according to the present embodiment, the remaining of voids in the bonding material 50 can be prevented. As a result, an increase in heat resistance between the semiconductor chip 20 and the first electrode terminal 40 can be prevented. Therefore, during the operation of the semiconductor device 10, a decrease in the amount of heat transmitted from the semiconductor device 10 to the first electrode terminal 40 can be prevented. Accordingly, in the present embodiment, during the operation of the semiconductor device 10, an excessive increase in the temperature of the semiconductor device 10 can be prevented.

According to the present embodiment, the semiconductor device 10 includes: the semiconductor chip 20 having the first chip surface 20a facing the upper side, that is, the first side (+D1 side) of the first direction D1 and having the second chip surface 20c facing the lower side, that is, the second side (−D1 side) of the first direction D1; the first electrode terminal 40 facing the first chip surface 20a in the first direction D1; the second electrode terminal 30 facing the second chip surface 20c in the first direction D1; and the bonding material 50 configured to bond at least the semiconductor chip 20 and each of the first electrode terminal 40 and the second electrode terminal 30 and formed of a solder. The bonding material 50 includes the first bonding material 55 and the second bonding material 56 bonded to the first bonding material 55, the first bonding material 55 includes the first bonding layer 61 bonded to the first chip surface 20a, the second bonding material 56 includes the second bonding layer 62 configured to bond the first bonding layer 61 and the first electrode terminal 40, and the second proportion R2 that is the proportion of weight of lead in the second bonding material 56 is less than the first proportion R1 that is the proportion of weight of lead in the first bonding material 55. In the present embodiment, as described above, in a state where the first bonding layer 61 is opened to the upper side, the first reflow step P012 can be performed. Therefore, even when the warpage of the semiconductor chip 20 in the first reflow step P012 is large, the void B1 can be discharged from the liquid first bonding layer 61L to the outside of the first bonding layer 61L. In addition, since the second proportion R2 is less than the first proportion R1, the melting point of the second bonding layer 62 can be reduced. As a result, the second reflow temperature T2 in the second reflow step P015 can be reduced. Therefore, as described above, the warpage of the semiconductor chip 20 in the second reflow step P015 can be reduced. As a result, as described above, in the second reflow step P015, the void B2 can be discharged from the end portion of the liquid second bonding layer 62L to the outside of the second bonding layer 62L. Further, the second reflow temperature T2 in the second reflow step P015 can be reduced. Therefore, in the second reflow step P015, the melting of the first bonding layer 61 can be prevented. As a result, in the second reflow step P015, the formation of the void B1 in the first bonding layer 61 can be prevented. As a result, the amount of voids remaining in the bonding material 50 can be suitably reduced. Therefore, as described above, during the operation of the semiconductor device 10, a decrease in the amount of heat transmitted from the semiconductor chip 20 to the first electrode terminal 40 can be prevented. Accordingly, an excessive increase in the temperature of the semiconductor chip 20 can be prevented.

In addition, in the present embodiment, as described above, in the second reflow step P015, a part of lead atoms in the first bonding layer 61 is diffused to the second bonding layer 62. Therefore, the second proportion R2 of the second bonding layer 62 can be increased. As a result, the melting point of the second bonding layer 62 can be increased. Therefore, as described above, the melting of the second bonding layer 62 in the mounting step Pm of mounting the semiconductor device 10 on a printed circuit board can be suitably prevented. As a result, a decrease in the bonding strength of the bonding material 50 in the mounting step Pm can be prevented. Therefore, electrical connection between the semiconductor chip 20 and the first electrode terminal 40 can be stabilized. Accordingly, the stabilization of the operation of the semiconductor device 10 can be facilitated.

According to the present embodiment, the first bonding material 55 includes the third bonding layer 63 configured to bond the second chip surface 20c and the second electrode terminal 30. Accordingly, the melting point of the third bonding layer 63 can be increased as compared to when the third bonding layer 63 is formed of the second bonding material 56. Therefore, the melting of the third bonding layer 63 in the mounting step Pm can be prevented. As a result, a decrease in the bonding strength of the third bonding layer 63 in the mounting step Pm can be prevented. Therefore, electrical connection between the semiconductor chip 20 and the second electrode terminal 30 can be stabilized. Accordingly, the stabilization of the operation of the semiconductor device 10 can be more suitably facilitated.

According to the present embodiment, the thickness t2 of the second bonding layer 62 is less than the thickness t1 of the first bonding layer 61. Accordingly, an excessive increase in the volume of the second bonding layer 62 can be prevented. Therefore, in the second reflow step P015, the second proportion R2 of the second bonding layer 62 is likely to be increased by lead atoms diffused from the first bonding layer 61 to the second bonding layer 62. As a result, the melting point of the second bonding layer 62 can be stably increased. Therefore, the melting of the second bonding layer 62 in the mounting step Pm can be more suitably prevented. Accordingly, electrical connection between the semiconductor chip 20 and the first electrode terminal 40 can be more suitably stabilized. Therefore, the stabilization of the operation of the semiconductor device 10 can be more suitably facilitated.

In addition, in the present embodiment, as described above, the second proportion R2 of the second bonding layer 62 is likely to be increased. Therefore, an excessive increase in the reflow time of the second reflow step P015 is likely to be prevented. As a result, an increase in man-hours of the second reflow step P015 is likely to be prevented. Accordingly, an increase in manufacturing man-hours of the semiconductor device 10 can be prevented.

According to the present embodiment, the first proportion R1 that is the proportion of weight of lead in the first bonding material 55 is 92% or more and 99% or less, and the second proportion R2 that is the proportion of weight of lead in the second bonding material 56 is 88% or more and 92% or less. Accordingly, each of the melting point of the first bonding material 55 and the melting point of the second bonding material 56 can be set to be 260° C. or higher. Therefore, the melting of the bonding material 50 in the mounting step Pm can be prevented.

Accordingly, electrical connection between the semiconductor chip 20 and each of the first electrode terminal 40 and the second electrode terminal 30 can be stabilized. Therefore, the stabilization of the operation of the semiconductor device 10 can be facilitated.

In the present embodiment, the first bonding material 55 includes silver. As a result, the strength of the first bonding layer 61 and the strength of the third bonding layer 63 can be increased. Therefore, damage to each of the first bonding layer 61 and the third bonding layer 63 by thermal stress or the like applied to the bonding material 50 during the use of the semiconductor device 10 can be prevented. As a result, electrical connection between the semiconductor chip 20 and each of the first electrode terminal 40 and the second electrode terminal 30 can be more suitably stabilized. Accordingly, the stabilization of the operation of the semiconductor device 10 can be more suitably facilitated.

According to the present embodiment, the second bonding material 56 includes silver, and the third proportion R3 that is the proportion of weight of silver in the first bonding material 55 is more than the fourth proportion R4 that is the proportion of weight of silver in the second bonding material 56. Accordingly, an excessive decrease in the third proportion R3 can be prevented. As a result, the strength of the first bonding layer 61 and the strength of the third bonding layer 63 can be more suitably increased. As a result, damage to each of the first bonding layer 61 and the third bonding layer 63 during the use of the semiconductor device 10 can be more suitably prevented. Accordingly, the stabilization of the operation of the semiconductor device 10 can be more suitably facilitated.

According to the present embodiment, the second bonding material 56 includes at least one of bismuth and indium. Accordingly, the melting point of the second bonding material 56 can be reduced. Accordingly, the second reflow temperature T2 in the second reflow step P015 can be suitably reduced. Therefore, an increase in the warpage of the semiconductor chip 20 in the second reflow step P015 can be prevented, and the melting of the first bonding material 55 can be prevented. As a result, as described above, the amount of voids remaining in the bonding material 50 can be suitably reduced. Therefore, a decrease in the amount of heat transmitted from the semiconductor chip 20 to the first electrode terminal 40 can be more suitably prevented. Accordingly, during the operation of the semiconductor device 10, an excessive increase in the temperature of the semiconductor chip 20 can be more suitably prevented.

According to the present embodiment, the method of manufacturing the semiconductor device 10 includes: the bonding step Pj1 of forming the bonding material 50, in which the bonding step Pj1 includes the first reflow step P012 of reflowing each of the first bonding layer 61P provided on the first chip surface 20a and the third bonding layer 63P provided on the second chip surface 20c, the second bonding material application step P013 of applying the second bonding layer 62P to the first bonding layer 61, the placement step P014 of placing the first electrode terminal 40 on the second bonding layer 62P, and the second reflow step P015 of reflowing the second bonding layer 62P, and the second reflow temperature T2 that is the reflow temperature in the second reflow step P015 is lower than the first reflow temperature T1 that is the reflow temperature in the first reflow step P012. Accordingly, as described above, in a state where the first bonding layer 61 is opened to the upper side, the first reflow step P012 can be performed. Therefore, even when the warpage of the semiconductor chip 20 in the first reflow step P012 is large, the void B1 can be discharged from the liquid first bonding layer 61L to the outside of the first bonding layer 61L. In addition, the second reflow temperature T2 can be reduced. Therefore, as described above, in the second reflow step P015, the void B2 can be discharged from the end portion of the liquid second bonding layer 62L to the outside of the second bonding layer 62L, and the formation of the void B1 in the first bonding layer 61 can be prevented. As a result, the amount of voids remaining in the bonding material 50 can be suitably reduced. Therefore, as described above, during the operation of the semiconductor device 10, a decrease in the amount of heat transmitted from the semiconductor chip 20 to the first electrode terminal 40 can be prevented. Accordingly, an excessive increase in the temperature of the semiconductor chip 20 can be prevented.

### Second Embodiment

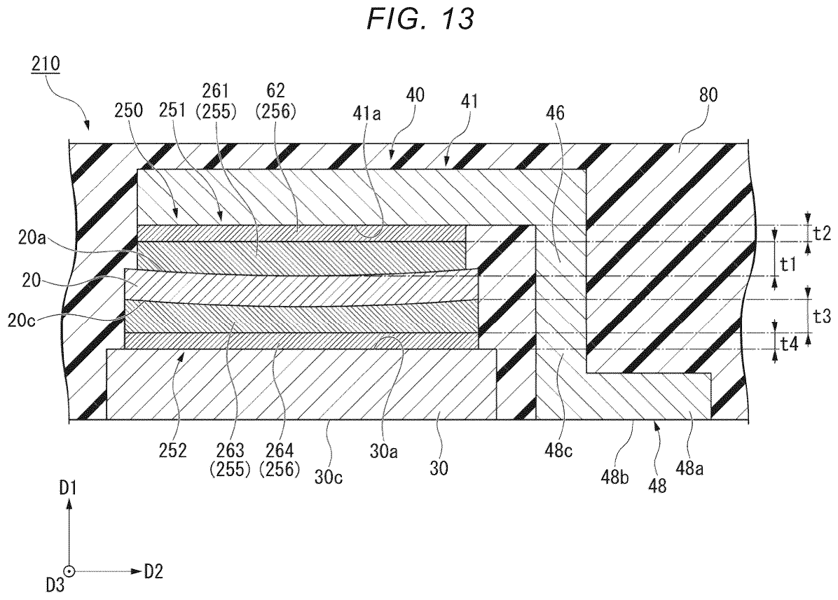

FIG. 13 is a cross-sectional view illustrating a semiconductor device 210 according to the present embodiment. A second bonding material 256 according to the present embodiment includes a fourth bonding layer 264 configured to bond a third bonding layer 263 and the second electrode terminal 30. In the following description, components according to the same aspect as that of the first embodiment will be represented by the same reference numerals, and the description thereof will not be repeated. The semiconductor device 210 according to the present embodiment includes the semiconductor chip 20, the first electrode terminal 40, the second electrode terminal 30, the external terminal 48, a bonding material 250, and the resin portion 80.

The bonding material 250 bonds the semiconductor chip 20 and each of the first electrode terminal 40 and the second electrode terminal 30. The bonding material 250 includes a first bonding portion 251 and a second bonding portion 252. In addition, the bonding material 250 includes a first bonding material 255 and the second bonding material 256.

In the up-down direction, the first bonding portion 251 is positioned between the semiconductor chip 20 and the to-be-bonded portion 41. The first bonding portion 251 bonds the semiconductor chip 20 and the first electrode terminal 40. As a result, the semiconductor chip 20 and the first electrode terminal 40 are electrically connected through the first bonding portion 251.

In the up-down direction, the second bonding portion 252 is positioned between the semiconductor chip 20 and the second electrode terminal 30. The second bonding portion 252 bonds the semiconductor chip 20 and the second electrode terminal 30. As a result, the semiconductor chip 20 and the second electrode terminal 30 are electrically connected through the second bonding portion 252.

Each of the first bonding material 255 and the second bonding material 256 is formed of a solder. In the present embodiment, the first proportion R1 of the first bonding material 255 is 92% or more and 99% or less. The melting point of the first bonding material 255 is 275° C. or higher. As described below, the first bonding material 255 is formed by plating in a plating step P021. The first bonding material 255 includes a first bonding layer 261 and the third bonding layer 263. The other configurations and the like of the first bonding material 255 according to the present embodiment are the same as the other configurations and the like of the first bonding material 55 according to the first embodiment.

In the present embodiment, the second proportion R2 of the second bonding material 256 is 88% or more and 92% or less. In the present embodiment, the proportion of weight of lead in the second bonding material 256 is less than the proportion of weight of lead in the first bonding material 255. The melting point of the second bonding material 256 is 260° C. or higher. As described below, in a reflow step P025, the second bonding material 256 is formed by solidifying the liquid second bonding material 256 that is melted by reflowing the paste-like second bonding material 256. The second bonding material 256 includes the second bonding layer 62 and the fourth bonding layer 264. The other configurations and the like of the second bonding material 256 according to the present embodiment are the same as the other configurations and the like of the second bonding material 56 according to the first embodiment.

The first bonding portion 251 includes the first bonding layer 261 and the second bonding layer 62. The first bonding layer 261 is bonded to the first chip surface 20a of the semiconductor chip 20. The second bonding layer 62 bonds the first bonding layer 261 and the first electrode terminal 40. That is, the second bonding material 256 is bonded to the first bonding material 255. As a result, the first bonding portion 251 bonds the semiconductor chip 20 and the first electrode terminal 40. In the present embodiment, a thickness t1 of the first bonding layer 261 is about 25 μm, and a thickness t2 of the second bonding layer 62 is about 5 μm. The thickness t2 of the second bonding layer 62 is less than the thickness t1 of the first bonding layer 261.

In the present embodiment, the second bonding portion 252 includes the third bonding layer 263 and the fourth bonding layer 264. The third bonding layer 263 is bonded to the second chip surface 20c. The fourth bonding layer 264 bonds the third bonding layer 263 and the second electrode terminal 30. That is, the second bonding material 256 is bonded to the first bonding material 255. As a result, the second bonding portion 252 bonds the semiconductor chip 20 and the second electrode terminal 30. In the present embodiment, a thickness t3 of the third bonding layer 263 is about 25 μm, and a thickness t4 of the fourth bonding layer 264 is about 5 μm. The thickness t4 of the fourth bonding layer 264 is less than the thickness t3 of the third bonding layer 263. The other configurations and the like of the bonding material 250 according to the present embodiment are the same as the other configurations and the like of the bonding material 50 according to the first embodiment. The other configurations and the like of the semiconductor device 210 according to the present embodiment are the same as the other configurations and the like of the semiconductor device 10 according to the first embodiment.

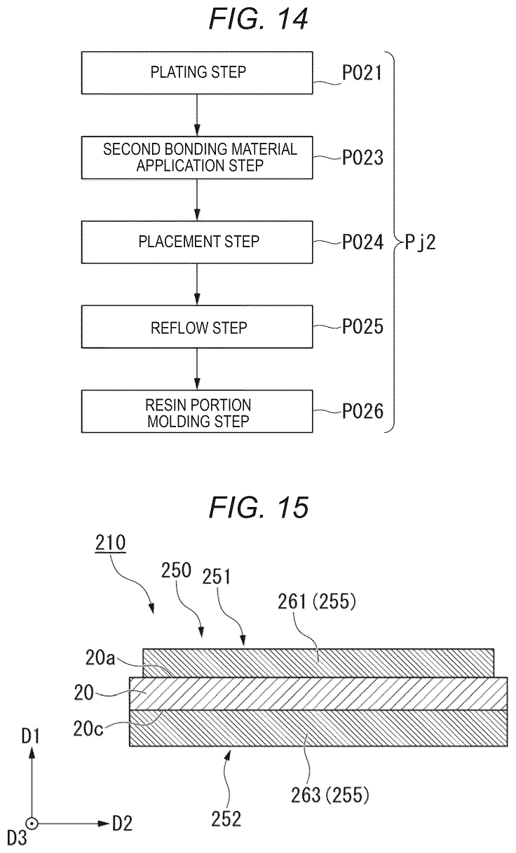

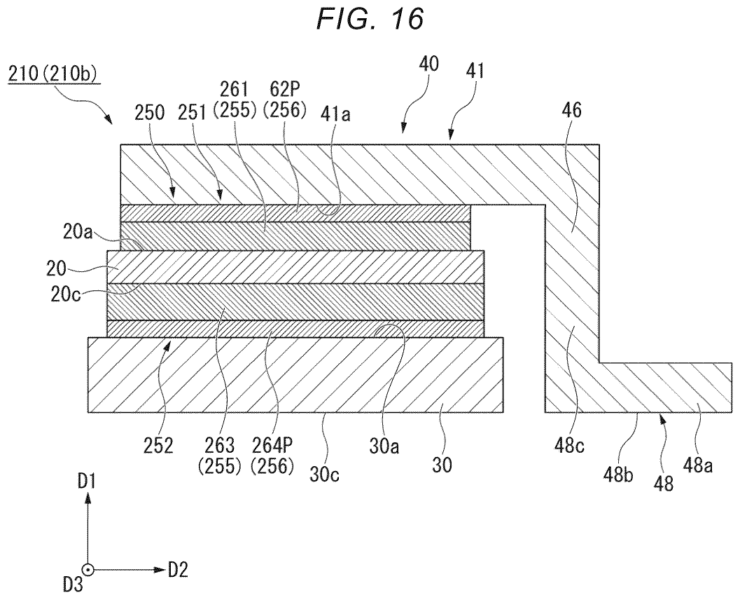

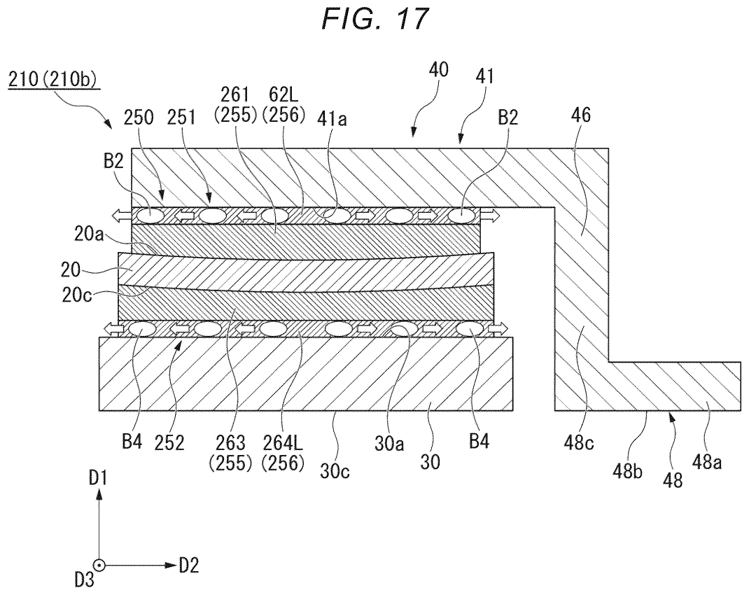

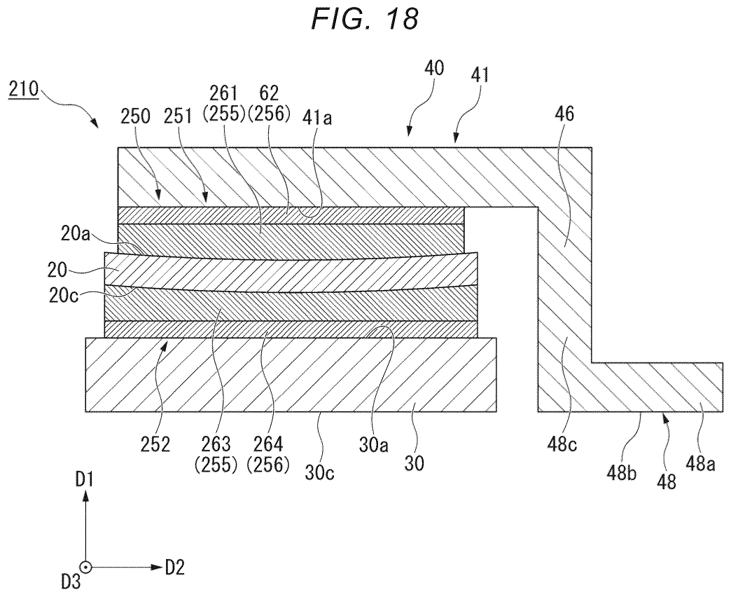

FIG. 14 is a flowchart illustrating a method of manufacturing the semiconductor device 210 according to the present embodiment. FIG. 15 is a first cross-sectional view illustrating the method of manufacturing the semiconductor device 210 according to the present embodiment. FIG. 16 is a second cross-sectional view illustrating the method of manufacturing the semiconductor device 210 according to the present embodiment. FIG. 17 is a third cross-sectional view illustrating the method of manufacturing the semiconductor device 210 according to the present embodiment. FIG. 18 is a fourth cross-sectional view illustrating the method of manufacturing the semiconductor device 210 according to the present embodiment. Next, the method of manufacturing the semiconductor device 210 according to the present embodiment will be described. As illustrated in FIG. 14, the method of manufacturing the semiconductor device 210 according to the present embodiment includes a bonding step Pj2 of forming the bonding material 250. The bonding step Pj2 includes a plating step P021 of forming the first bonding layer 261 and the third bonding layer 263 on the first chip surface 20a and the second chip surface 20c of the semiconductor chip 20, respectively, a second bonding material application step P023 of applying the paste-like fourth bonding layer 264P and the paste-like second bonding layer 62P to the second electrode terminal 30 and the first bonding layer 261, respectively, a placement step P024 of placing the third bonding layer 263 on the fourth bonding layer 264P and placing the first electrode terminal 40 on the second bonding layer 62P, a reflow step P025 of reflowing each of the second bonding layer 62P and the fourth bonding layer 264P, and a resin portion molding step P026 of molding the resin portion 80.

In the plating step P021, as illustrated in FIG. 15, the operator and the like perform plating on the semiconductor chip 20. The first bonding layer 261 and the third bonding layer 263 are formed on the first chip surface 20a and the second chip surface 20c of the semiconductor chip 20, respectively. Therefore, the formation of voids in the first bonding layer 261 and the third bonding layer 263 can be prevented. When the operator and the like form the first bonding layer 261 and the third bonding layer 263, the plating step P021 ends.

In the second bonding material application step P023, the paste-like fourth bonding layer 264P and the paste-like second bonding layer 62P are applied to the second electrode terminal 30 and the first bonding layer 261, respectively. As illustrated in FIG. 16, the operator and the like apply the paste-like fourth bonding layer 264P to the second bonding surface 30a of the second electrode terminal 30. Further, the operator and the like apply the paste-like second bonding layer 62P to the first bonding layer 261. When the operator and the like apply the fourth bonding layer 264P and the second bonding layer 62P to the second electrode terminal 30 and the first bonding layer 261, respectively, the second bonding material application step P023 ends.

In the placement step P024, the third bonding layer 263 is placed on the fourth bonding layer 264P, and the first electrode terminal 40 is placed on the second bonding layer 62P. As a result, the fourth bonding layer 264P is in contact with the third bonding layer 263, and the second bonding layer 62P is in contact with the first electrode terminal 40. When the operator and the like place the third bonding layer 263 on the fourth bonding layer 264P and place the first electrode terminal 40 on the second bonding layer 62P, the placement step P024 ends. In the following description, the semiconductor device 210 when the placement step P024 ends may also be referred to as a semiconductor device 210b before bonding.

In the reflow step P025, each of the second bonding layer 62P and the fourth bonding layer 264P is reflowed. The operator and the like heat the semiconductor device 210b before bonding in a heating furnace (not illustrated), for example, in a vacuum to melt each of the second bonding layer 62P and the fourth bonding layer 264P. Next, the operator and the like take out the semiconductor device 210b before bonding from the heating furnace for cooling to solidify the liquid second bonding layer 62L and the liquid fourth bonding layer 264L.

As described above, the melting point of the second bonding layer 62P and the melting point of the fourth bonding layer 264P are about 183° C. Therefore, a reflow temperature T2 in the reflow step P025 is set to about 200° C. In the present embodiment, a reflow time in the reflow step P025 is set to a long time of about 4 hours. As described above, the melting point of the first bonding material 255 is 275° C. or higher. Therefore, in the reflow step P025, the melting of each of the first bonding layer 261 and the third bonding layer 263 can be prevented. As a result, in the reflow step P025, the formation of voids in each of the first bonding layer 261 and the third bonding layer 263 can be prevented.

As described above, the reflow temperature T2 is a low temperature of about 200° C. Therefore, as illustrated in FIG. 17, the warpage of the semiconductor chip 20 in the reflow step P025 can be reduced. Therefore, the gap in the up-down direction between each of an end portion of the semiconductor chip 20 in the second direction D2 and the end portion of the semiconductor chip 20 in the third direction D3 and the to-be-bonded portion 41 can be prevented from being excessively narrow. Accordingly, in the reflow step P025, a void B2 formed in the liquid second bonding layer 62L is discharged from an end portion of the second bonding layer 62L to the outside of the second bonding layer 62L. Further, a void B4 formed in the liquid fourth bonding layer 264L is discharged from an end portion of the fourth bonding layer 264L to the outside of the fourth bonding layer 264L. As a result, in the bonding step Pj2 according to the present embodiment, when each of the liquid second bonding layer 62L and the liquid fourth bonding layer 264L is solidified, as illustrated in FIG. 18, the remaining of the void B2 in the second bonding layer 62 can be prevented, and the remaining of the void B4 in the fourth bonding layer 264 can be prevented. As a result, as described above, in the reflow step P025, the formation of voids in each of the first bonding layer 261 and the third bonding layer 263 can be prevented. As a result, in the present embodiment, the remaining of voids in the bonding material 250 can be prevented. Therefore, during the operation of the semiconductor device 210, a decrease in the amount of heat transmitted from the semiconductor chip 20 to the first electrode terminal 40 can be prevented. Accordingly, an excessive increase in the temperature of the semiconductor chip 20 can be prevented.

As described above, in the reflow step P025, each of the first bonding layer 261 and the third bonding layer 263 is heated to the reflow temperature T2. Therefore, a part of lead atoms in the first bonding layer 261 is diffused to the liquid second bonding layer 62L. In addition, a part of lead atoms in the third bonding layer 263 is diffused to the liquid fourth bonding layer 264L. As a result, at a timing at which the reflow step P025 ends, the second proportion R2 in each of the second bonding layer 62 and the fourth bonding layer 264 can be increased to 88% or more and 92% or less. Accordingly, the melting point of each of the second bonding layer 62 and the fourth bonding layer 264 can be increased to 260° C. or higher. As described above, the melting point of the first bonding material 255 is 275° C. or higher. Accordingly, the melting of the bonding material 250 by reflowing in the mounting step Pm of mounting the semiconductor device 210 on a printed circuit board (not illustrated) can be suitably prevented. Therefore, in the mounting step Pm, a decrease in the bonding strength between the semiconductor chip 20 and each of the first electrode terminal 40 and the second electrode terminal 30 can be prevented. When the operator and the like solidify each of the liquid second bonding layer 62L and the liquid fourth bonding layer 264L, the reflow step P025 ends.

In the resin portion molding step P026, the operator and the like form the resin portion 80. The resin portion molding step P026 according to the present embodiment is the same as the resin portion molding step P016 according to the first embodiment. As illustrated in FIG. 13, when the operator and the like mold the resin portion 80, the resin portion molding step P026 ends. When the resin portion molding step P026 ends, the bonding step Pj2 of the semiconductor device 210 ends, and the semiconductor device 210 illustrated in FIG. 13 is manufactured.

According to the present embodiment, the first bonding material 255 includes the third bonding layer 263 bonded to the second chip surface 20c, and the second bonding material 256 includes the fourth bonding layer 264 configured to bond the third bonding layer 263 and the second electrode terminal 30. Accordingly, as described above, the reflow temperature T2 in the reflow step P025 can be reduced. Therefore, in the reflow step P025, the melting of the first bonding layer 261 can be prevented. As a result, in the reflow step P025, the formation of voids in the first bonding layer 261 can be prevented. Therefore, during the operation of the semiconductor device 210, a decrease in the amount of heat transmitted from the semiconductor chip 20 to the second electrode terminal 30 can be prevented. Accordingly, an excessive increase in the temperature of the semiconductor chip 20 can be more suitably prevented.

According to the present embodiment, the thickness t2 of the second bonding layer 62 is less than the thickness t1 of the first bonding layer 261, and the thickness t4 of the fourth bonding layer 264 is less than the thickness t3 of the third bonding layer 263. Accordingly, an excessive increase in the volume of each of the second bonding layer 62 and the fourth bonding layer 264 can be prevented. Therefore, in the reflow step P025, the proportion of weight of lead in the second bonding layer 62 is likely to be increased by lead atoms diffused from the first bonding layer 261 to the second bonding layer 62. Therefore, in the reflow step P025, the proportion of weight of lead in the fourth bonding layer 264 is likely to be increased by lead atoms diffused from the third bonding layer 263 to the fourth bonding layer 264. As a result, the melting point of each of the second bonding layer 62 and the fourth bonding layer 264 can be stably increased. Therefore, the melting of the second bonding layer 62 and the fourth bonding layer 264 in the mounting step Pm can be suitably prevented. Accordingly, electrical connection between the semiconductor chip 20 and each of the first electrode terminal 40 and the second electrode terminal 30 can be suitably stabilized. Therefore, the stabilization of the operation of the semiconductor device 210 can be suitably facilitated.

According to the present embodiment, the method of manufacturing the semiconductor device 210 includes the bonding step Pj2 of forming the bonding material 250, in which the bonding step Pj2 includes the plating step P021 of forming the first bonding layer 261 and the third bonding layer 263 on the first chip surface 20a and the second chip surface 20c, respectively, the second bonding material application step P023 of applying the fourth bonding layer 264P and the second bonding layer 62P to the second electrode terminal 30 and the first bonding layer 261, respectively, the placement step P024 of placing the third bonding layer 263 on the fourth bonding layer 264P and placing the first electrode terminal 40 on the second bonding layer 62P, and the reflow step P025 of reflowing each of the second bonding layer 62P and the fourth bonding layer 264P. Accordingly, each of the first bonding layer 261 and the third bonding layer 263 is formed by plating. As described above, the formation of voids in the first bonding layer 261 and the third bonding layer 263 can be prevented. In addition, the reflow temperature T2 can be reduced. Therefore, as described above, in the reflow step P025, the void B2 can be discharged from the end portion of the liquid second bonding layer 62L to the outside of the second bonding layer 62L, and the void B4 can be discharged from the end portion of the liquid fourth bonding layer 264L to the outside of the fourth bonding layer 264L. As a result, the amount of voids remaining in the bonding material 250 can be suitably reduced. Therefore, during the operation of the semiconductor device 210, a decrease in the amount of heat transmitted from the semiconductor chip 20 to the first electrode terminal 40 and the second electrode terminal 30 can be prevented. Accordingly, an excessive increase in the temperature of the semiconductor chip 20 can be prevented.

### Third Embodiment

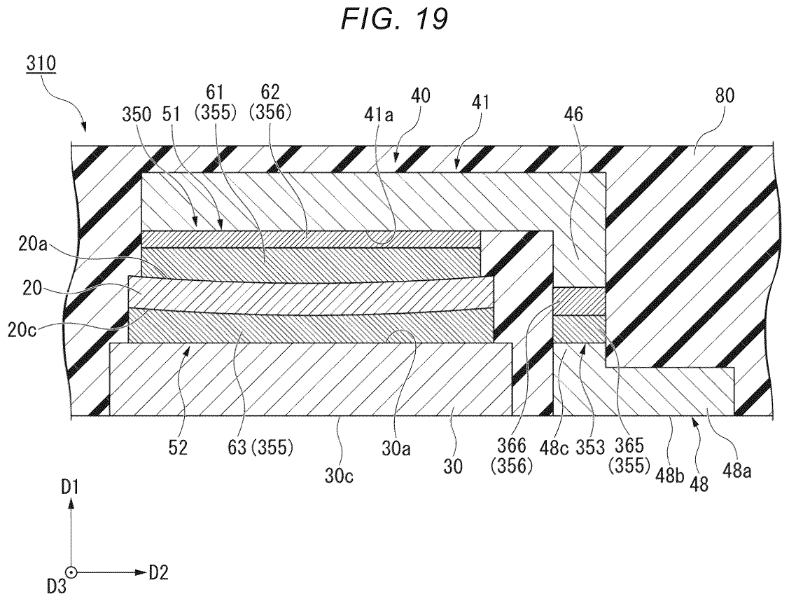

FIG. 19 is a cross-sectional view illustrating a semiconductor device 310 according to the present embodiment. A first bonding material 355 according to the present embodiment includes a fifth bonding layer 365, and a second bonding material 356 includes a sixth bonding layer 366. In the following description, components according to the same aspect as that of the first embodiment will be represented by the same reference numerals, and the description thereof will not be repeated. The semiconductor device 310 according to the present embodiment includes the semiconductor chip 20, the first electrode terminal 40, the second electrode terminal 30, the external terminal 48, a bonding material 350, and the resin portion 80. In the present embodiment, the first electrode terminal 40 and the external terminal 48 may be different members. The first electrode terminal 40 and the external terminal 48 are bonded by a third bonding portion 353 in the bonding material 350.

The bonding material 350 bonds the semiconductor chip 20 and each of the first electrode terminal 40 and the second electrode terminal 30. In addition, the bonding material 350 according to the present embodiment bonds the first electrode terminal 40 and the external terminal 48. The bonding material 350 includes the first bonding portion 51, the second bonding portion 52, and the third bonding portion 353. In addition, the bonding material 350 includes the first bonding material 355 and the second bonding material 356.

In the up-down direction, the third bonding portion 353 is positioned between the first connection portion 46 in the first electrode terminal 40 and the second connection portion 48c in the external terminal 48. The third bonding portion 353 bonds the first connection portion 46 and the second connection portion 48c. That is, the third bonding portion 353 bonds the first electrode terminal 40 and the external terminal 48. As a result, the external terminal 48 is electrically connected to the first electrode terminal 40 through the third bonding portion 353.

Each of the first bonding material 355 and the second bonding material 356 is formed of a solder. In the present embodiment, the first proportion R1 of the first bonding material 355 is 92% or more and 99% or less. The melting point of the first bonding material 355 is 275° C. or higher. The first bonding material 355 includes the first bonding layer 61, the third bonding layer 63, and the fifth bonding layer 365. The other configurations and the like of the first bonding material 355 according to the present embodiment are the same as the other configurations and the like of the first bonding material 55 according to the first embodiment.

In the present embodiment, the second proportion R2 of the second bonding material 356 is 88% or more and 92% or less. A proportion of weight of lead in the second bonding material 356 is less than a proportion of weight of lead in the first bonding material 355. The melting point of the second bonding material 356 is 260° C. or higher. The second bonding material 356 includes the second bonding layer 62 and the sixth bonding layer 366. The other configurations and the like of the second bonding material 356 according to the present embodiment are the same as the other configurations and the like of the second bonding material 56 according to the first embodiment.

The third bonding portion 353 includes the fifth bonding layer 365 and the sixth bonding layer 366. The fifth bonding layer 365 is bonded to a surface of the second connection portion 48c facing the upper side. As a result, the fifth bonding layer 365 is bonded to the external terminal 48. The sixth bonding layer 366 bonds the fifth bonding layer 365 and a surface of the first connection portion 46 facing the lower side. That is, the sixth bonding layer 366 bonds the fifth bonding layer 365 and the first electrode terminal 40. As a result, the third bonding portion 353 bonds the first electrode terminal 40 and the external terminal 48. The other configurations and the like of the bonding material 350 according to the present embodiment are the same as the other configurations and the like of the bonding material 50 according to the first embodiment. The other configurations and the like of the semiconductor device 310 according to the present embodiment are the same as the other configurations and the like of the semiconductor device 10 according to the first embodiment.

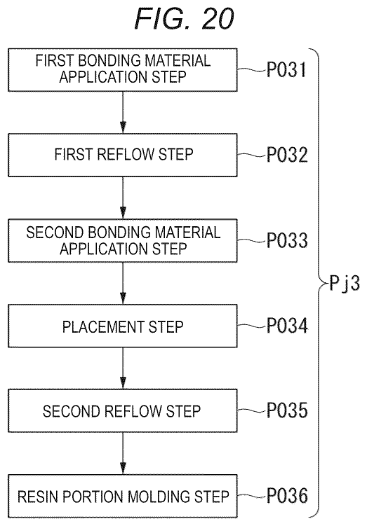

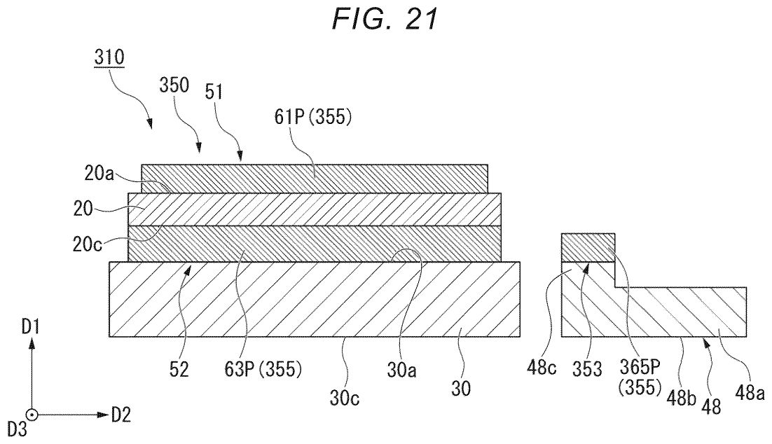

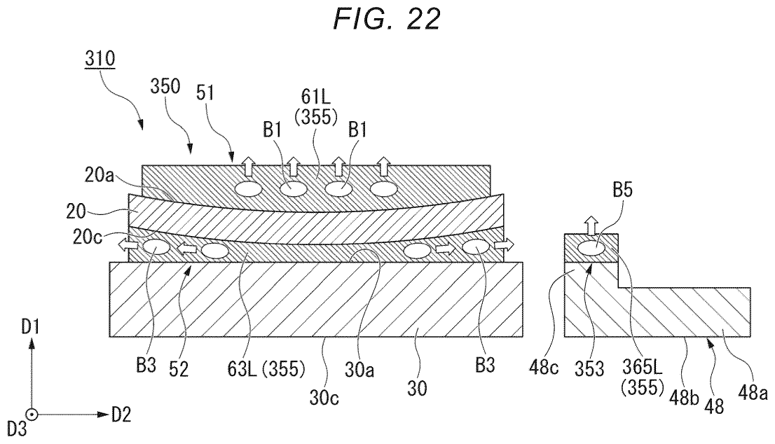

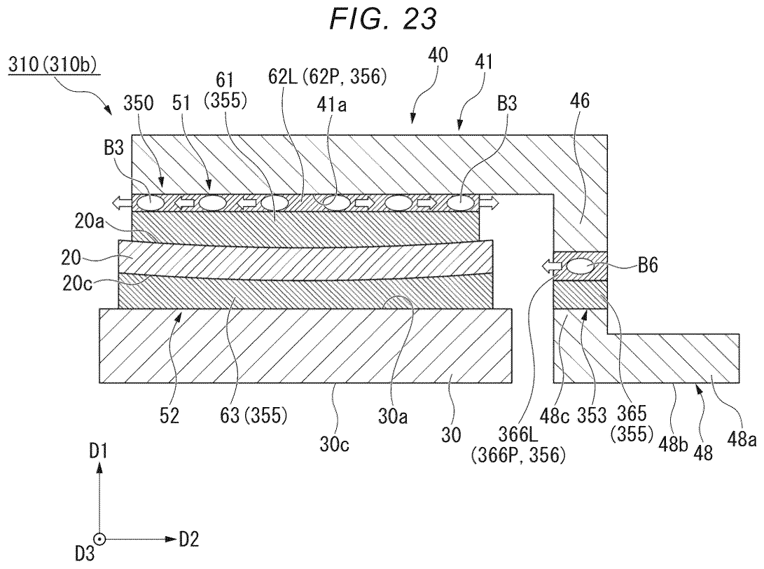

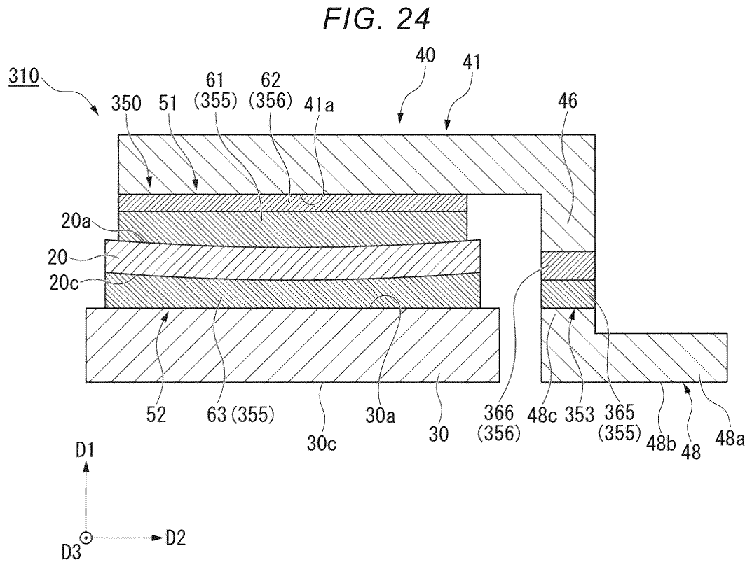

FIG. 20 is a flowchart illustrating a method of manufacturing the semiconductor device 310 according to the present embodiment. FIG. 21 is a first cross-sectional view illustrating the method of manufacturing the semiconductor device 310 according to the present embodiment. FIG. 22 is a second cross-sectional view illustrating the method of manufacturing the semiconductor device 310 according to the present embodiment. FIG. 23 is a third cross-sectional view illustrating the method of manufacturing the semiconductor device 310 according to the present embodiment. FIG. 24 is a fourth cross-sectional view illustrating the method of manufacturing the semiconductor device 310 according to the present embodiment. Next, the method of manufacturing the semiconductor device 310 according to the present embodiment will be described. As illustrated in FIG. 20, the method of manufacturing the semiconductor device 310 according to the present embodiment includes a bonding step Pj3 of forming the bonding material 350. The bonding step Pj3 includes a first bonding material application step P031, a first reflow step P032, a second bonding material application step P033, a placement step P034, a second reflow step P035, and a resin portion molding step P036.

In the first bonding material application step P031, first, as illustrated in FIG. 21, the operator and the like apply the paste-like third bonding layer 63P to the second bonding surface 30a of the second electrode terminal 30, and apply the paste-like fifth bonding layer 365P to the surface of the second connection portion 48c facing the upper side. Next, the operator and the like place the semiconductor chip 20 on the third bonding layer 63P. As a result, the third bonding layer 63P is in contact with each of the second chip surface 20c and the second bonding surface 30a. Next, the operator and the like apply the paste-like first bonding layer 61P to the first chip surface 20a of the semiconductor chip 20. At this time, each of the first bonding layer 61P and the fifth bonding layer 365P is opened to the upper side. When the operator and the like apply the first bonding layer 61P to the first chip surface 20a, the first bonding material application step P031 ends.

In the first reflow step P032, each of the first bonding layer 61P, the third bonding layer 63P, and the fifth bonding layer 365P is reflowed. In the first reflow step P032, the operator and the like heat the second electrode terminal 30 on which the semiconductor chip 20 is placed and the external terminal 48 in a heating furnace (not illustrated), for example, in a vacuum to melt each of the paste-like first bonding layer 61P, the paste-like third bonding layer 63P, and the paste-like fifth bonding layer 365P. Next, the operator and the like take out the second electrode terminal 30 and the external terminal 48 from the heating furnace for cooling to solidify the liquid first bonding layer 61L, the liquid third bonding layer 63L, and the liquid fifth bonding layer 365L. The first reflow temperature T1 is set to about 350° C.

As illustrated in FIG. 22, in the first reflow step P032, the void B3 formed in the liquid third bonding layer 63L is discharged from the end portion of the third bonding layer 63L to the outside of the third bonding layer 63L. In addition, the void B1 formed in the liquid first bonding layer 61L is discharged from an upper end of the first bonding layer 61L to the outside of the first bonding layer 61L. Further, a void B5 formed in the liquid fifth bonding layer 365L is discharged from an upper end of the fifth bonding layer 365L to the outside of the fifth bonding layer 365L. As a result, in the bonding step Pj1 according to the present embodiment, as illustrated in FIG. 23, the remaining of voids in each of the first bonding layer 61, the third bonding layer 63, and the fifth bonding layer 365 can be prevented. When the operator and the like solidify the liquid first bonding layer 61L, the liquid third bonding layer 63L, and the liquid fifth bonding layer 365L, the first reflow step P032 ends.

In the second bonding material application step P033, the operator and the like apply the paste-like second bonding layer 62P to the first bonding layer 61, and apply the paste-like sixth bonding layer 366P to the fifth bonding layer 365.

In the placement step P034, the first electrode terminal 40 is placed on the second bonding layer 62P and the sixth bonding layer 366P. More specifically, the operator and the like place the to-be-bonded portion 41 on the second bonding layer 62P, and place the first connection portion 46 on the sixth bonding layer 366P. As a result, the second bonding layer 62P is in contact with each of the first bonding layer 61 and the first bonding surface 41a. In addition, the sixth bonding layer 366P is in contact with each of the fifth bonding layer 365 and the first connection portion 46. When the operator and the like place the first electrode terminal 40 on the second bonding layer 62P and the sixth bonding layer 366P, the placement step P034 ends. In the following description, the semiconductor device 310 when the placement step P034 ends may also be referred to as a semiconductor device 310b before bonding.

In the second reflow step P035, each of the second bonding layer 62P and the sixth bonding layer 366P is reflowed. The operator and the like heat the semiconductor device 310b before bonding in a heating furnace (not illustrated), for example, in a vacuum to melt each of the second bonding layer 62P and the sixth bonding layer 366P. Next, the operator and the like take out the semiconductor device 310b before bonding from the heating furnace for cooling to solidify the liquid second bonding layer 62L and the liquid sixth bonding layer 366L.

A second reflow temperature T2 in the second reflow step P035 is set to about 200° C. In the present embodiment, a reflow time in the second reflow step P035 is set to a long time of about 4 hours. As described above, the melting point of the first bonding material 355 is 275° C. or higher. Therefore, in the second reflow step P035, the melting of each of the first bonding layer 61, the third bonding layer 63, and the fifth bonding layer 365 can be prevented. As a result, in the second reflow step P035, the formation of voids in each of the first bonding layer 61, the third bonding layer 63, and the fifth bonding layer 365 can be prevented.

As described above, the second reflow temperature T2 is a low temperature of about 200° C. Therefore, as illustrated in FIG. 23, the warpage of the semiconductor chip 20 in the second reflow step P035 can be reduced. Therefore, in the second reflow step P035, the void B3 formed in the liquid second bonding layer 62L is discharged from the end portion of the second bonding layer 62L to the outside of the second bonding layer 62L. In addition, a void B6 formed in the liquid sixth bonding layer 366L is discharged from an end portion of the sixth bonding layer 366L to the outside of the sixth bonding layer 366L. As a result, in the bonding step Pj3 of the present embodiment, as illustrated in FIG. 24, the remaining of voids in the bonding material 350 can be prevented. Therefore, during the operation of the semiconductor device 310, a decrease in the amount of heat transmitted from the semiconductor chip 20 to the first electrode terminal 40 can be prevented. Accordingly, an excessive increase in the temperature of the semiconductor chip 20 can be prevented.

In addition, in the second reflow step P035, a part of lead atoms in the first bonding layer 61 is diffused to the liquid second bonding layer 62L. Further, a part of lead atoms in the fifth bonding layer 365 is diffused to the liquid sixth bonding layer 366L. As a result, at a timing at which the second reflow step P035 ends, the second proportion R2 in each of the second bonding layer 62 and the sixth bonding layer 366 can be increased to 88% or more and 92% or less. As a result, the melting point of each of the second bonding layer 62 and the sixth bonding layer 366 can be increased to 260° C. or higher. Accordingly, in the mounting step Pm, the melting of the second bonding layer 62 and the sixth bonding layer 366 can be suitably prevented. Therefore, in the mounting step Pm, a decrease in the bonding strength between the semiconductor chip 20 and each of the first electrode terminal 40 and the second electrode terminal 30 can be prevented. In addition, in the mounting step Pm, a decrease in the bonding strength between the first electrode terminal 40 and the external terminal 48 can be prevented. When the operator and the like solidify each of the liquid second bonding layer 62L and the liquid sixth bonding layer 366L, the second reflow step P035 ends.

In the resin portion molding step P036, the operator and the like form the resin portion 80. The resin portion molding step P036 according to the present embodiment is the same as the resin portion molding step P016 according to the first embodiment. As illustrated in FIG. 19, when the operator and the like mold the resin portion 80, the resin portion molding step P036 ends. When the resin portion molding step P036 ends, the bonding step Pj3 of the semiconductor device 310 ends, and the semiconductor device 310 illustrated in FIG. 19 is manufactured.

According to the present embodiment, the semiconductor device 310 includes the external terminal 48 electrically connected to the first electrode terminal 40, and the first bonding material 355 includes the fifth bonding layer 365 bonded to the external terminal 48. The second bonding material 356 includes the sixth bonding layer 366 configured to bond the fifth bonding layer 365 and the first electrode terminal 40. Accordingly, as described above, in the second reflow step P035, a part of lead atoms in the fifth bonding layer 365 is diffused to the sixth bonding layer 366. Therefore, the second proportion R2 of the sixth bonding layer 366 can be increased. As a result, the melting point of the sixth bonding layer 366 can be increased. Therefore, as described above, the melting of the sixth bonding layer 366 in the mounting step Pm of mounting the semiconductor device 310 on a printed circuit board can be suitably prevented. As a result, a decrease in the bonding strength of the third bonding portion 353 in the mounting step Pm can be prevented. Therefore, electrical connection between the first electrode terminal 40 and the external terminal 48 can be stabilized. Accordingly, the stabilization of the operation of the semiconductor device 310 can be facilitated.

According to the above-described embodiment, the proportion of weight of lead in the second bonding material is less than the proportion of weight of lead in the first bonding material. As a result, a semiconductor device capable of preventing an excessive increase in the temperature of the semiconductor chip can be prevented.

The semiconductor device according to the embodiment includes the aspects of the following supplementary notes.

### Supplementary Note 1

A semiconductor device including:
a semiconductor chip having a first chip surface facing a first side of a first direction and having a second chip surface facing a second side of the first direction;
a first electrode terminal facing the first chip surface in the first direction;
a second electrode terminal facing the second chip surface in the first direction; and
a bonding material configured to bond at least the semiconductor chip and each of the first electrode terminal and the second electrode terminal and formed of a solder,
in which the bonding material includes a first bonding material and a second bonding material bonded to the first bonding material,
the first bonding material includes a first bonding layer bonded to the first chip surface,
the second bonding material includes a second bonding layer configured to bond the first bonding layer and the first electrode terminal, and
a proportion of weight of lead in the second bonding material is less than a proportion of weight of lead in the first bonding material.

### Supplementary Note 2

The semiconductor device according to Supplementary Note 1,
in which the first bonding material includes a third bonding layer configured to bond the second chip surface and the second electrode terminal.

### Supplementary Note 3

The semiconductor device according to Supplementary Note 2,
in which a thickness of the second bonding layer is less than a thickness of the first bonding layer.

### Supplementary Note 4

The semiconductor device according to Supplementary Note 1,
in which the first bonding material includes a third bonding layer bonded to the second chip surface, and
the second bonding material includes a fourth bonding layer configured to bond the third bonding layer and the second electrode terminal.

### Supplementary Note 5

The semiconductor device according to Supplementary Note 4,
in which a thickness of the second bonding layer is less than a thickness of the first bonding layer, and
a thickness of the fourth bonding layer is less than a thickness of the third bonding layer.

### Supplementary Note 6

The semiconductor device according to any one of Supplementary Notes 1 to 5, further including an external terminal electrically connected to the first electrode terminal,
in which the first bonding material includes a fifth bonding layer bonded to the external terminal, and
the second bonding material includes a sixth bonding layer configured to bond the fifth bonding layer and the first electrode terminal.

### Supplementary Note 7

The semiconductor device according to any one of Supplementary Notes 1 to 6,
in which a proportion of weight of lead in the first bonding material is 92% or more and 99% or less, and
a proportion of weight of lead in the second bonding material is 88% or more and 92% or less.

### Supplementary Note 8

The semiconductor device according to any one of Supplementary Notes 1 to 7,
in which the first bonding material includes silver.

### Supplementary Note 9

The semiconductor device according to Supplementary Note 8,
in which the second bonding material includes silver, and
a proportion of weight of silver in the first bonding material is more than a proportion of weight of silver in the second bonding material.

### Supplementary Note 10

The semiconductor device according to any one of Supplementary Notes 1 to 9,
wherein the second bonding material includes at least one of bismuth and indium.

### Supplementary Note 11

A method of manufacturing a semiconductor device including a semiconductor chip having a first chip surface facing a first side of a first direction and having a second chip surface facing a second side of the first direction, a first electrode terminal facing the first chip surface in the first direction, a second electrode terminal facing the second chip surface in the first direction, and a bonding material configured to bond at least the semiconductor chip and each of the first electrode terminal and the second electrode terminal and formed of a solder,
the method including a bonding step of forming the bonding material,
in which the bonding material includes a first bonding material and a second bonding material bonded to the first bonding material,
a proportion of weight of lead in the second bonding material is less than a proportion of weight of lead in the first bonding material,
the first bonding material includes a first bonding layer bonded to the first chip surface and a third bonding layer configured to bond the second chip surface and the second electrode terminal,
the second bonding material includes a second bonding layer configured to bond the first bonding layer and the first electrode terminal,
the bonding step includes
a first reflow step of reflowing each of the first bonding layer provided on the first chip surface and the third bonding layer provided on the second chip surface,
a second bonding material application step of applying the second bonding layer to the first bonding layer,
a placement step of placing the first electrode terminal on the second bonding layer, and
a second reflow step of reflowing the second bonding layer, and
a reflow temperature in the second reflow step is lower than a reflow temperature in the first reflow step.

### Supplementary Note 12

A method of manufacturing a semiconductor device including a semiconductor chip having a first chip surface facing a first side of a first direction and having a second chip surface facing a second side of the first direction, a first electrode terminal facing the first chip surface in the first direction, a second electrode terminal facing the second chip surface in the first direction, and a bonding material configured to bond at least the semiconductor chip and each of the first electrode terminal and the second electrode terminal and formed of a solder,
the method including a bonding step of forming the bonding material,
in which the bonding material includes a first bonding material and a second bonding material bonded to the first bonding material,
a proportion of weight of lead in the second bonding material is less than a proportion of weight of lead in the first bonding material,
the first bonding material includes a first bonding layer bonded to the first chip surface and a third bonding layer bonded to the second chip surface,
the second bonding material includes a second bonding layer configured to bond the first bonding layer and the first electrode terminal and a fourth bonding layer configured to bond the third bonding layer and the second electrode terminal, and
the bonding step includes
a plating step of forming the first bonding layer and the third bonding layer on the first chip surface and the second chip surface, respectively,
a second bonding material application step of applying the fourth bonding layer and the second bonding layer to the second electrode terminal and the first bonding layer, respectively,
a placement step of placing the third bonding layer on the fourth bonding layer and placing the first electrode terminal on the second bonding layer, and
a reflow step of reflowing each of the second bonding layer and the fourth bonding layer.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a semiconductor chip having a first chip surface facing a first direction and a second chip surface facing opposite the first direction;
a first electrode terminal that faces the first chip surface;
a second electrode terminal that faces the second chip surface and is bonded to the second chip surface;
a bonding material comprising solder that bonds the first chip surface of the semiconductor chip to the first electrode terminal, wherein the bonding material includes a first bonding material having a first bonding layer, and a second bonding material having a second bonding layer bonded to the first bonding material and the first electrode terminal, wherein
a proportion of weight of lead in the second bonding material is less than a proportion of weight of lead in the first bonding material.

2. The semiconductor device according to claim 1, further comprising:
another bonding material comprising solder that bonds the second electrode terminal to the second chip surface.

3. The semiconductor device according to claim 2, wherein the another bonding material is a same material as the first bonding material.

4. The semiconductor device according to claim 1,
wherein a thickness of the second bonding layer is less than a thickness of the first bonding layer.

5. The semiconductor device according to claim 2,
wherein the another bonding material includes a third bonding layer bonded to the second chip surface, and
the another bonding material includes a fourth bonding layer bonded to the third bonding layer and the second electrode terminal.

6. The semiconductor device according to claim 5,
wherein a thickness of the second bonding layer is less than a thickness of the first bonding layer, and
a thickness of the fourth bonding layer is less than a thickness of the third bonding layer.

7. The semiconductor device according to claim 1, further comprising an external terminal electrically connected to the first electrode terminal,
wherein the first bonding material includes a fifth bonding layer bonded to the external terminal, and
the second bonding material includes a sixth bonding layer bonded to the fifth bonding layer and the first electrode terminal.

8. The semiconductor device claim 1,
wherein a proportion of weight of lead in the first bonding material is in an inclusive range of 92% or more and 99% or less, and
a proportion of weight of lead in the second bonding material is in an inclusive range of 88% or more and 92% or less.

9. The semiconductor device claim 3,
wherein a proportion of weight of lead in the first bonding material is in an inclusive range of 92% or more and 99% or less, and
a proportion of weight of lead in the second bonding material is in an inclusive range of 88% or more and 92% or less.

10. The semiconductor device claim 7,
wherein a proportion of weight of lead in the first bonding material is in an inclusive range of 92% or more and 99% or less, and
a proportion of weight of lead in the second bonding material is in an inclusive range of 88% or more and 92% or less.

11. The semiconductor device according to claim 1,
wherein the first bonding material includes silver.

12. The semiconductor device according to claim 3,
wherein the first bonding material includes silver.

13. The semiconductor device according to claim 7,
wherein the first bonding material includes silver.

14. The semiconductor device according to claim 1,
wherein the second bonding material includes silver, and
a proportion of weight of silver in the first bonding material is more than a proportion of weight of silver in the second bonding material.

15. The semiconductor device according to claim 3,
wherein the second bonding material includes silver, and
a proportion of weight of silver in the first bonding material is more than a proportion of weight of silver in the second bonding material.

16. The semiconductor device according to claim 7,
wherein the second bonding material includes silver, and
a proportion of weight of silver in the first bonding material is more than a proportion of weight of silver in the second bonding material.

17. The semiconductor device according to claim 1,
wherein the second bonding material includes at least one of bismuth and indium.

18. The semiconductor device according to claim 3,
wherein the second bonding material includes at least one of bismuth and indium.

19. A semiconductor device comprising:
a semiconductor chip having a first chip surface facing a first direction and a second chip surface facing opposite the first direction;
a first electrode terminal that faces the first chip surface;
a second electrode terminal that faces the second chip surface and is bonded to the second chip surface; and
a bonding material comprising solder that that bonds the first chip surface of the semiconductor chip to the first electrode terminal, wherein the bonding material includes a first bonding material having a first bonding layer, and a second bonding material having a second bonding layer bonded to the first bonding material and the first electrode terminal, wherein
a melting point of the first bonding material is higher than that for the second bonding material.

20. A semiconductor device comprising:
a semiconductor chip having a first chip surface that substantially faces a first direction and a second chip surface substantially facing opposite the first direction;
a first electrode terminal that faces the first chip surface;
a second electrode terminal that faces the second chip surface and is bonded to the second chip surface;
a bonding material comprising solder that that bonds the first chip surface of the semiconductor chip to the first electrode terminal, wherein the bonding material includes a first bonding material having a first bonding layer, and a second bonding material having a second bonding layer bonded to the first bonding material and the first electrode terminal; and
means for preventing a gap between the bonding material and the first chip surface, wherein the first chip surface is warped with a center of the first chip surface further from the first electrode terminal than ends of the first chip surface.
